(19) United States
(12) Patent Application Publication
(10) Pub. No.: US 2026/0080960 A1
(43) Pub. Date: Mar. 19, 2026

(54) SEMICONDUCTOR DEVICE, MEMORY SYSTEM AND INFORMATION PROCESSING SYSTEM

(71) Applicant: Kioxia Corporation, Tokyo (JP)

(72) Inventors: Daizaburo MIYAHARA, Tokyo (JP); Akira YAMAGUCHI, Yokohama (JP)

(73) Assignee: Kioxia Corporation, Tokyo (JP)

(21) Appl. No.: 19/013,330

(22) Filed: Jan. 8, 2025

(30) Foreign Application Priority Data
Sep. 18, 2024 (JP) 2024-161130

(51) Int. Cl. G11C 29/02; G11C 29/00

(52) U.S. Cl. CPC G11C 29/022; G11C 29/702; G11C 29/848

(57) ABSTRACT

According to one embodiment, a memory system includes a first semiconductor device and a controller. The first semiconductor device includes a first chip having a first temperature sensor. The controller includes a comparison circuit makes a comparison between a first measurement temperature of the first temperature sensor and first temperature data and outputs a first comparison result, and makes a comparison between the first measurement temperature and second temperature data and outputs a second comparison result, and a detection circuit performs detection of a defect in the first temperature sensor based on the first and second comparison results, and outputs a first detection result. The first chip switches a first use temperature based on the first detection result.

### CROSS-REFERENCE TO RELATED APPLICATIONS

This application is based upon and claims the benefit of priority from Japanese Patent Application No. 2024-161130, filed Sep. 18, 2024, the entire contents of which are incorporated herein by reference.

### FIELD

Embodiments described herein relate generally to a semiconductor device, a memory system and an information processing system.

### BACKGROUND

An information processing system including a host device and a memory system is known. The memory system includes a semiconductor device and a memory controller configured to control the semiconductor device. A NAND flash memory is known as such a semiconductor device.

### BRIEF DESCRIPTION OF THE DRAWINGS

FIG. 1 is a block diagram showing an example of a configuration of an information processing system according to a first embodiment.

FIG. 2 is a block diagram showing an example of a hardware configuration of a host device included in the information processing system according to the first embodiment.

FIG. 3 is a block diagram showing an example of a configuration of a memory system included in the information processing system according to the first embodiment.

FIG. 4 is a block diagram showing an example of a configuration of a NAND flash memory within the memory system included in the information processing system according to the first embodiment.

FIG. 5 is a circuit diagram showing an example of a circuit configuration of a memory cell array within the NAND flash memory included in the information processing system according to the first embodiment.

FIG. 6 is a cross-sectional view showing an example of a cross-sectional structure of the memory system included in the information processing system according to the first embodiment.

FIG. 7 is a circuit diagram showing an example of a configuration of a temperature sensor within the NAND flash memory included in the information processing system according to the first embodiment.

FIG. 8 is a diagram illustrating an example of a configuration of a comparison circuit within a memory controller included in the information processing system according to the first embodiment.

FIG. 9 is a circuit diagram showing an example of a configuration of a detection circuit within the memory controller included in the information processing system according to the first embodiment.

FIG. 10 is a diagram illustrating an example of a configuration of a generation circuit within the memory controller included in the information processing system according to the first embodiment.

FIG. 11 is a flowchart showing an example of a defective temperature sensor detection operation in the information processing system according to the first embodiment.

FIG. 12 is a diagram illustrating an example of the defective temperature sensor detection operation in the information processing system according to the first embodiment.

FIG. 13 is a diagram showing an example of temperature sensor data and a threshold of each NAND flash memory in the information processing system according to the first embodiment.

FIG. 14 is a diagram illustrating an example of an operation of the comparison circuit within the memory controller included in the information processing system according to the first embodiment.

FIG. 15 is a diagram illustrating an example of an operation of the detection circuit within the memory controller included in the information processing system according to the first embodiment.

FIG. 16 is a diagram illustrating an example of an operation of the generation circuit within the memory controller included in the information processing system according to the first embodiment.

FIG. 17 is a diagram illustrating an example of an operation of the temperature sensor within the NAND flash memory included in the information processing system according to the first embodiment.

FIG. 18 is a diagram illustrating an example of an operation of the temperature sensor within the NAND flash memory included in the information processing system according to the first embodiment.

FIG. 19 is a diagram illustrating an example of a configuration of a comparison circuit within a memory controller included in an information processing system according to a first modification of the first embodiment.

FIG. 20 is a diagram illustrating an example of a configuration of a generation circuit within the memory controller included in the information processing system according to the first modification of the first embodiment.

FIG. 21 is a diagram illustrating an example of a defective temperature sensor detection operation in the information processing system according to the first modification of the first embodiment.

FIG. 22 is a diagram illustrating an example of a configuration of a comparison circuit within a memory controller included in an information processing system according to a second modification of the first embodiment.

FIG. 23 is a diagram illustrating an example of a configuration of a generation circuit within the memory controller included in the information processing system according to the second modification of the first embodiment.

FIG. 24 is a diagram illustrating an example of a defective temperature sensor detection operation in the information processing system according to the second modification of the first embodiment.

FIG. 25 is a diagram illustrating an example of a configuration of a generation circuit within a memory controller included in an information processing system according to a third modification of the first embodiment.

FIG. 26 is a diagram illustrating an example of a defective temperature sensor detection operation in the information processing system according to the third modification of the first embodiment.

FIG. 27 is a block diagram showing an example of a functional configuration of a host device included in the information processing system according to a second embodiment.

FIG. 28 is a block diagram showing an example of a configuration of a memory system included in the information processing system according to the second embodiment.

FIG. 29 is a diagram illustrating an example of a defective temperature sensor detection operation in the information processing system according to the second embodiment.

FIG. 30 is a block diagram showing an example of a configuration of a memory system included in an information processing system according to a third embodiment.

FIG. 31 is a planar view showing an example of a planar structure of the memory system included in the information processing system according to the third embodiment.

FIG. 32 is a cross-sectional view showing an example of a cross-sectional structure of a package of the memory system included in the information processing system according to the third embodiment.

FIG. 33 is a block diagram showing an example of a configuration of a NAND flash memory within a memory system included in an information processing system according to a fourth embodiment.

FIG. 34 is a circuit diagram showing an example of a configuration of a temperature sensor within the NAND flash memory included in the information processing system according to the fourth embodiment.

### DETAILED DESCRIPTION

In general, according to one embodiment, a memory system includes a first semiconductor device and a controller. The first semiconductor device includes a first chip. The first chip includes a first temperature sensor. The controller includes a comparison circuit and a detection circuit. The comparison circuit makes a comparison between a first measurement temperature measured by the first temperature sensor and first temperature data and outputs a result of the comparison as a first comparison result, and makes a comparison between the first measurement temperature and second temperature data and outputs a result of the comparison as a second comparison result. The detection circuit performs detection of a defect in the first temperature sensor based on the first comparison result and the second comparison result, and outputs a result of the detection as a first detection result. The first chip switches a first use temperature based on the first detection result.

Hereinafter, an embodiment will be described with reference the accompanying drawings. In the following description, constituent elements having substantially the same function and configuration will be assigned the same reference symbol. In a case where elements having similar configurations are distinguished from each other in particular, their identical reference symbols may be assigned different letters or numbers.

### 1. First Embodiment

### 1.1 Configuration

### 1.1.1 Configuration of Information Processing System

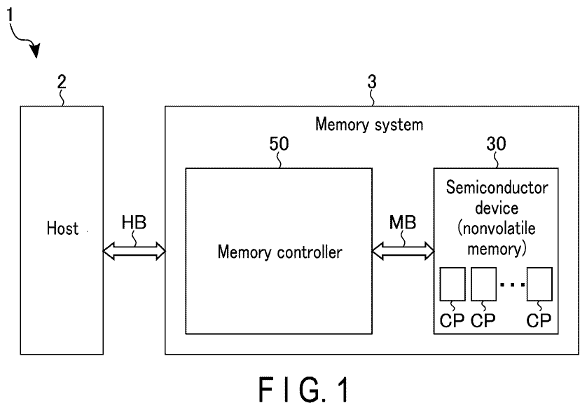

A configuration of an information processing system according to a first embodiment will be described with reference to FIG. 1. FIG. 1 is a block diagram showing an example of a configuration of an information processing system according to a first embodiment. As shown in FIG. 1, an information processing system 1 includes a host device (hereinafter referred to as a “host”) 2 and a memory system 3. The host 2 and the memory system 3 are coupled to each other via a host bus HB. The memory system 3 includes a semiconductor device 30 and a memory controller 50. The semiconductor device 30 includes one or more chips CP. The semiconductor device 30 and the memory controller 50 are coupled to each other via a memory bus MB. The memory controller 50 controls the semiconductor device 30.

The present embodiment will describe an exemplary case in which the semiconductor device 30 is a nonvolatile memory, and the chip CP is a NAND flash memory. Hereinafter, the semiconductor device 30 will be referred to as a “nonvolatile memory 30”, and the chip CP will be referred to as a “NAND chip CP”.

The host 2 is a device configured to control the memory system 3. Examples of the host 2 include a personal computer, a server system, a mobile device, a vehicle-mounted device, and a digital camera.

The memory system 3 is a device configured to store data. Examples of the memory system 3 include a solid-state drive (SSD), a universal flash storage (UFS) device, a universal serial bus (USB) memory, a multi-media card (MMC), and SD™ card. The memory system 3 performs processing based on a request signal received from the host 2 or a voluntary processing request. The memory system 3 includes the nonvolatile memory 30 and the memory controller 50.

The nonvolatile memory 30 is a device configured to store data nonvolatilely. The nonvolatile memory 30 is coupled to the memory controller 50 via the memory bus MB. The nonvolatile memory 30 nonvolatilely stores data received from, for example, the memory controller 50 via the memory bus MB.

The memory controller 50 is a device configured to control the nonvolatile memory 30. The memory controller 50 is, for example, a system-on-a-chip (SoC). The memory controller 50 is coupled to the host 2 via the host bus HB. The memory controller 50 receives a request signal and information from the host 2 via the host bus HB. Furthermore, the memory controller 50 transmits information to the host 2 via the host bus HB.

The type of host bus HB depends on an application applied to the memory system 3. In the case of the memory system 3 being an SSD, for example, an interface under serial attached SCSI (SAS), serial ATA (SATA), or the peripheral component interconnect express (PCIe™) standard is used for the host bus HB. In the case of the memory system 3 being a UFS device, an interface under the M-PHY standard is used for the host bus HB. In the case of the memory system 3 being a USB memory, an interface under the USB standard is used for the host bus HB. In the case of the memory system 3 being an MMC, an interface under the Embedded Multi Media Card (eMMC) standard is used for the host bus HB. In the case of the memory system 3 being an SD™ card, an interface under the SD™ standard is used for the host bus HB.

The memory controller 50 controls the nonvolatile memory 30 via the memory bus MB based on a request signal received from the host 2 or a voluntary processing request. The memory controller 50 transmits and receives data to and from, for example, the nonvolatile memory 30, and transmits a command and an address thereto. The memory bus MB transmits and receives signals in compliance with a NAND interface.

### 1.1.2 Configuration of Host

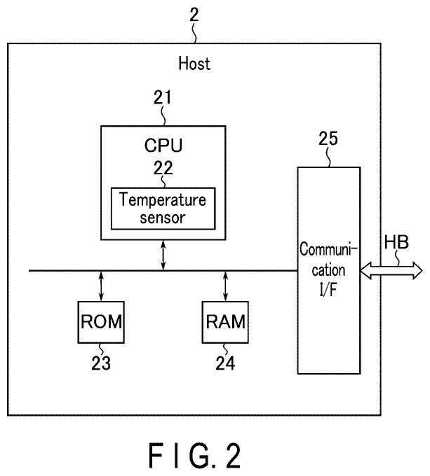

A configuration of the host 2 will be described with reference to FIG. 2. FIG. 2 is a block diagram showing an example of a hardware configuration of the host 2 included in the information processing system 1 according to the first embodiment. As shown in FIG. 2, the host 2 includes, for example, a central processing unit (CPU) 21, a read only memory (ROM) 23, a random-access memory (RAM) 24, and a communication interface (I/F) circuit 25.

The CPU 21 is a processor configured to execute various programs relating to control of the host 2. The CPU 21 includes a temperature sensor 22. The temperature sensor 22 measures a temperature of the CPU 21. The temperature sensor 22 is a temperature measurement circuit that is prepared by applying, for example, a band gap reference circuit, etc., and is mounted inside the host 2. Other examples of the temperature sensor 22 include a thermocouple. Hereinafter, temperature data measured by the temperature sensor 22 will be referred to as “temperature sensor data TempH”. The CPU 21 transmits a request signal and information via the communication interface circuit 25. The ROM 23 is a nonvolatile memory configured to store a control program of the host 2. The RAM 24 is a volatile memory used as a work area of the CPU 21. Examples of the RAM 24 include a static random-access memory (SRAM) and a dynamic random-access memory (DRAM). The communication interface circuit 25 is an interface circuit used for communications with the memory system 3.

### 1.1.3 Configuration of Memory System

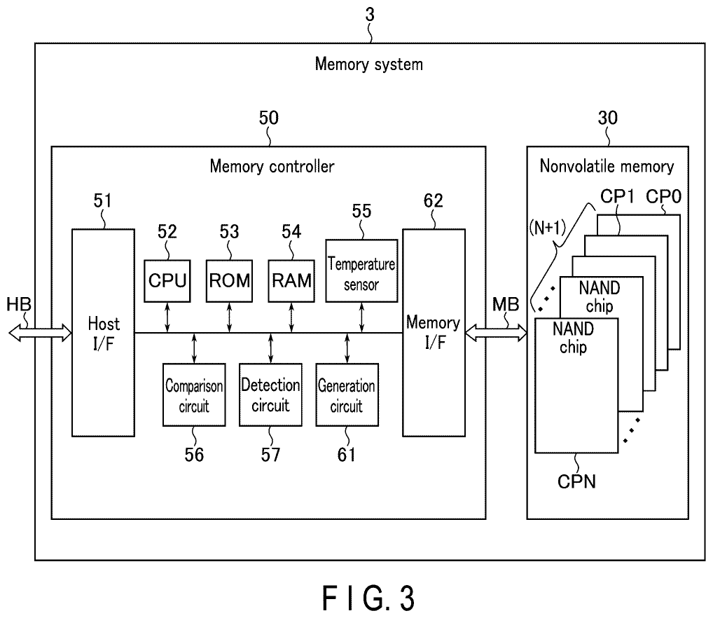

A configuration of the memory system 3 will be described with reference to FIG. 3. FIG. 3 is a block diagram showing an example of a configuration of the memory system 3.

### 1.1.3.1 Configuration of Nonvolatile Memory

An internal configuration of the nonvolatile memory 30 will be described. As shown in FIG. 3, the nonvolatile memory 30 includes, for example, (N+1) (where N is an integer equal to or greater than 2) NAND chips CP. Hereinafter, (N+1) NAND chips CP will be referred to as CP0, CP1, . . . , and CPN, respectively. In a case where the NAND chips CP0 to CPN are not distinguished from each other, they will be simply referred to as a NAND chip CP.

The NAND chip CP is a device configured to store data nonvolatilely. The NAND chip CP includes a plurality of memory cell transistors. Each of the memory cell transistors stores data nonvolatilely. The NAND chip CP performs a write operation, a read operation, an erase operation, etc., based on a command, an address, etc., received from the memory controller 50. In the write operation, the NAND chip CP nonvolatilely store data received from the memory controller 50 in a plurality of memory cell transistors. In the read operation, the NAND chip CP outputs data read from the plurality of memory cell transistors to the memory controller 50.

Each of the (N+1) memory NAND chips CP is independently operable. Each of the NAND chips CP is coupled to the memory controller 50 via the memory bus MB. The number of memory buses MB and the number of NAND chips CP coupled to a single memory bus MB are freely selected. Communications between the memory controller 50 and the NAND chip CP are compliant with, for example, a single data rate (SDR) interface, a toggle double data rate (DDR) interface, or an open NAND flash interface (ONFI).

### 1.1.3.1.1 Configuration of NAND Chip

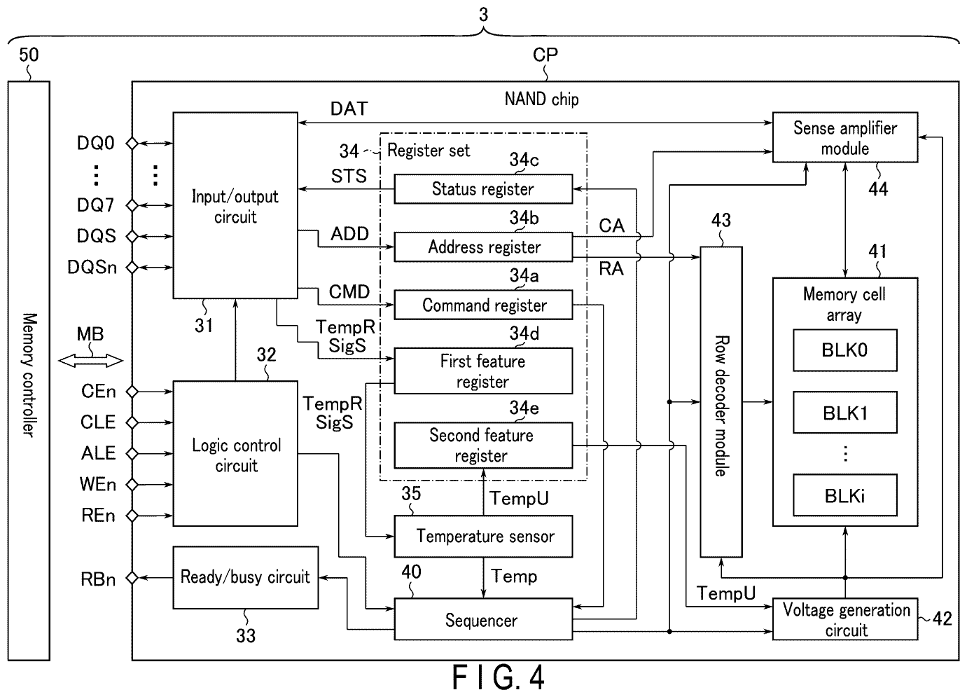

A configuration of the NAND chip CP will be described with reference to FIG. 4. FIG. 4 is a block diagram showing an example of a configuration of the NAND chip CP. FIG. 4 shows a configuration of one of the NAND chips CP included in the nonvolatile memory 30. The other NAND chips CP included in the nonvolatile memory 30 have similar configurations to the configuration shown in FIG. 4. FIG. 4 shows the memory controller 50, too.

As shown in FIG. 4, the NAND chip CP includes an input/output circuit 31, a logic control circuit 32, a ready/busy circuit 33, a register set 34, a temperature sensor 35, a sequencer 40, a memory cell array 41, a voltage generation circuit 42, a row decoder module 43, and a sense amplifier module 44.

The input/output circuit 31 is a circuit configured to transmit and receive signals and information to and from the memory controller 50. The input/output circuit 31 transmits and receives an input/output signal DQ (for example, 8-bit signals DQ0 to DQ7), and data strobe signals DQS and DQSn (an inversion signal of the signal DQS) to and from the memory controller 50.

The signal DQ includes, for example, a command CMD, an address ADD, status information STS, data DAT, replacement temperature data (hereinafter also referred to as an “input temperature”) TempR, and a switch signal SigS. The replacement temperature data TempR is replacement temperature data of temperature sensor data (hereinafter also referred to as a “measurement temperature”) Temp measured by the temperature sensor 35. The switch signal SigS is a signal for switching between use of internal data (temperature sensor data Temp) of the temperature sensor 35 and use of external data (replacement temperature data TempR) of the temperature sensor 35, as temperature data for use in the NAND chip CP. The replacement temperature data TempR and the switch signal SigS are used by, for example, the temperature sensor 35.

The signals DQS and DQSn are signals for controlling the timing of transmitting and receiving the signal DQ. For example, at the time of writing data, the signals DQS and DQSn along with the data DQ including the write data are transmitted from the memory controller 50 to the NAND chip CP. The NAND chip CP receives the signal DQ including the write data in synchronization with the signals DQS and DQSn. At the time of reading data, the signals DQS and DQSn along with the signal DQ including the read data are transmitted from the NAND chip CP to the memory controller 50. The memory controller 50 receives the signal DQ including the read data in synchronization with the signals DQS and DQSn.

The input/output circuit 31 may receive the signals DQS and DQSn from the memory controller 50 via the logic control circuit 32.

The input/output circuit 31 transmits the command CMD in the signal DQ to a command register 34a to be described later. The input/output circuit 31 transmits the address ADD in the signal DQ to an address register 34b to be described later. The input/output circuit 31 receives the status information STS from a status register 34c to be described later. The input/output circuit 31 transmits the replacement temperature data TempR and the switch signal SigS in the signal DQ to a first feature register 34d to be described later. The input/output circuit 31 transmits and receives the data DAT in the signal DQ to and from the sense amplifier module 44.

The logic control circuit 32 is a circuit configured to control the input/output circuit 31 and the sequencer 40 based on a control signal. The logic control circuit 32 receives a control signal from the memory controller 50. Examples used as such a control signal include a chip enable signal CEn, a command latch enable signal CLE, an address latch enable signal ALE, a write enable signal WEn, and a read enable signal REn. The signal CEn is a signal for enabling the NAND chip CP. The signal CLE is a signal indicating that the signal DQ received by the NAND chip CP is the command CMD. The signal ALE is a signal indicating that the signal DQ received by the NAND chip CP is the address ADD. The signal WEn is a signal instructing the NAND chip CP to input the signal DQ. The signal REn is a signal instructing the NAND chip CP to output the signal DQ. The NAND chip CP generates the signals DQS and DQSn based on the signal REn. The NAND chip CP outputs the signal DQ to the memory controller 50 based on the generated signals DQS and DQSn. The logic control circuit 32 controls the input/output circuit 31 and the sequencer 40 based on the received control signal.

The ready/busy circuit 33 is a circuit configured to notify the memory controller 50 of an operation status of the sequencer 40. The ready/busy circuit 33 transmits the ready/busy signal RBn to the memory controller 50 based on an operation status of the sequencer 40. The signal RBn is a signal indicative of whether the NAND chip CP is in a ready state or a busy state. The signal RBn is set to a “low” level, for example, in a case where the NAND chip CP is in a busy state. The ready state is a state in which the NAND chip CP can receive a command from the memory controller 50. The busy state is a state in which the NAND chip CP cannot receive a command from the memory controller 50.

The register set 34 is a set of circuits each configured to temporarily store information. The register set 34 includes the command register 34a, the address register 34b, the status register 34c, the first feature register 34d, and a second feature register 34e.

The command register 34a is a circuit configured to store the command CMD. The command CMD includes, for example, an instruction for causing the sequencer 40 to execute a read operation, a write operation, an erase operation, etc.

The address register 34b is a circuit configured to store the address ADD. The address ADD includes, for example, a row address RA (including a block address and a page address) and a column address CA. The block address, the page address, and the column address CA are used to select, for example, a block BLK, a word line, and a bit line, respectively. For example, the address register 34b transfers the row address RA to the row decoder module 43. The address register 34b transfers the column address CA to the sense amplifier module 44.

The status register 34c is a circuit configured to store, for example, the status information STS in the read operation, the write operation, and the erasure operation. The status information STS is used to notify the memory controller 50 of whether or not the operation has been completed successfully.

The first feature register 34d is a circuit configured to store various types of set information input from an outside of the NAND chip CP. The aforementioned set information includes, for example, the replacement temperature data TempR and the switch signal SigS.

The second feature register 34e is a circuit configured to store various types of set information to be used inside the NAND chip CP. The aforementioned set information includes, for example, use temperature data (hereinafter also referred to as a “use temperature”) TempU. The use temperature data TempU is temperature data for use in the NAND chip CP. The use temperature data TempU is used by, for example, the voltage generation circuit 42.

The temperature sensor 35 measures a temperature of the NAND chip CP. The temperature sensor 35 is a temperature measurement circuit that is prepared by applying, for example, a band gap reference circuit, etc., and is mounted inside the semiconductor device 30. Other examples of the temperature sensor 35 include a thermocouple. For example, the temperature sensor 35 measures a temperature of the memory cell array 41 inside the NAND chip CP. The temperature sensor 35 transmits a measured temperature as the temperature sensor data Temp to the sequencer 40. The temperature sensor 35 may not directly measure a temperature of the memory cell array 41. For example, the temperature sensor 35 may measure a temperature of a portion other than the memory cell array 41 inside the NAND chip CP. The temperature sensor 35 acquires the replacement temperature data TempR and the switch signal SigS from the first feature register 34d. The temperature sensor 35 selects either the temperature sensor data Temp or the replacement temperature data TempR based on the switch signal SigS, and transmits the selected temperature data as the use temperature data TempU to the second feature register 34e. As described above, the temperature sensor 35 can switch between a measured temperature and a temperature input from an outside and output the switched temperature as the use temperature data TempU. The temperature sensor 35 will be described later in detail.

The sequencer 40 is a circuit configured to control an operation of another circuit in accordance with a predetermined program. The sequencer 40 controls the operation of the entire NAND chip CP. For example, the sequencer 40 controls the ready/busy circuit 33, the voltage generation circuit 42, the row decoder module 43, and the sense amplifier module 44 based on the command CMD stored in the command register 34a. For example, the sequencer 40 executes the read operation, the write operation, and the erase operation. Furthermore, the sequencer 40 stores the temperature sensor data Temp acquired from the temperature sensor 35 as the status information STS in the status register 34c, and outputs the stored data to the memory controller 50 via the input/output circuit 31. The temperature sensor data Temp may be output to the memory controller 50 not as the status information STS but as information other than the status information STS. Furthermore, the sequencer 40 stores the replacement temperature data TempR and the signal SigS received from the memory controller 50 in the first feature register 34d.

The memory cell array 41 includes a plurality of blocks BLK0 to BLKi (where i is an integer equal to or greater than 1). Hereinafter, in a case where the blocks BLK0 to BLKi are not distinguished from each other, they will be simply referred to as a block BLK. The block BLK is, for example, a set of memory cell transistors data of which is erased in batch. The block BLK is, for example, used as a unit of data erasure. A plurality of bit lines and a plurality of word lines are provided in the memory cell array 41. The memory cell transistor is associated with, for example, a single bit line and a single word line. The memory cell array 41 will be described later in detail.

The voltage generation circuit 42 is a circuit configured to generate a voltage for use in each of the various operations. The voltage generation circuit 42 acquires the use temperature data TempU from the second feature register 34e. The voltage generation circuit 42 generates a voltage based on the use temperature data TempU. The voltage generation circuit 42 supplies the generated voltage to, for example, the memory cell array 41, the row decoder module 43, and the sense amplifier module 44.

The row decoder module 43 is a circuit configured to select one corresponding block BLK in the memory cell array 41 based on the row address RA. The row decoder module 43 transfers the voltage applied to the signal line corresponding to the selected word line to the selected word line in the selected block BLK.

The sense amplifier module 44 is a circuit configured to determine data stored in the memory cell transistor. In the read operation, the sense amplifier module 44 determines data stored in the memory cell transistor based on the voltage of the bit line (by applying the voltage to the bit line and judging whether or not a current flows through the bit line). The sense amplifier module 44 transfers a result of the determination as the read data DAT to the input/output circuit 31. Furthermore, in the write operation, the sense amplifier module 44 applies a voltage, which is based on the write data DAT received from the input/output circuit 31, to the bit line.

### 1.1.3.1.2 Circuit Configuration of Memory Cell Array

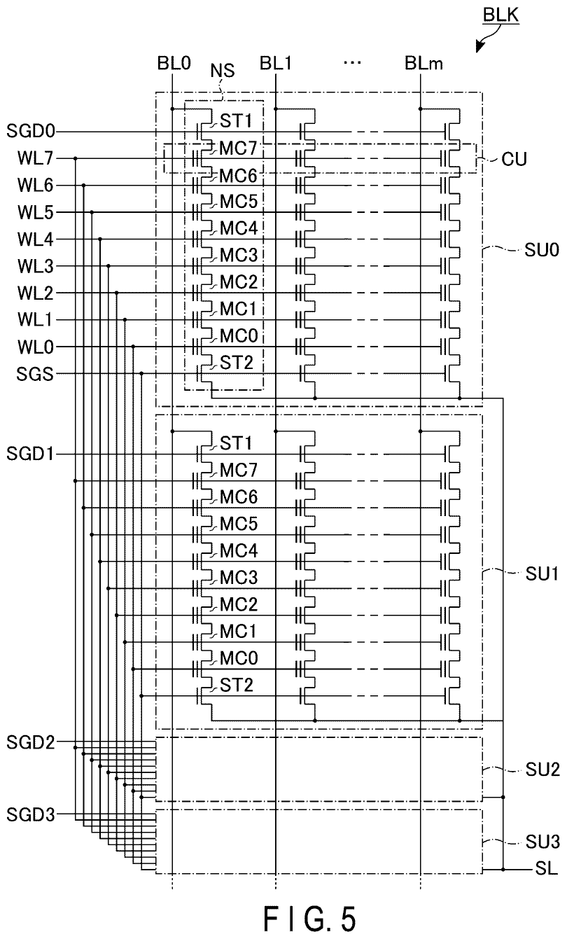

A circuit configuration of the memory cell array 41 will be described with reference to FIG. 5. FIG. 5 is a circuit diagram showing an example of a circuit configuration of the memory cell array 41. FIG. 5 shows a circuit configuration of the block BLK included in the memory cell array 41, as an example of a circuit configuration of the memory cell array 41. The other blocks BLK included in the memory cell array 41 have similar configurations to the configuration shown in FIG. 5.

As shown in FIG. 5, the block BLK includes, for example, four string units SU0 to SU3. Hereinafter, in a case where the string units SU0 to SU3 are not distinguished from each other, they will be simply referred to as a “string unit SU”. Each string unit SU is, for example, a set of NAND strings NS which are selected in batch in the write operation or the read operation. The string unit SU includes a plurality of NAND strings NS respectively associated with bit lines BL0 to BLm (where m is an integer equal to or greater than 1). Hereinafter, in a case where the bit lines BL0 to BLm are not distinguished from each other, they will be simply referred to as a “bit line BL”. Each of the NAND strings NS is a set of memory cell transistors coupled in series. The NAND string NS includes, for example, memory cell transistors MC0 to MC7 and select transistors ST1 and ST2. Hereinafter, in a case where the memory cell transistors MC0 to MC7 are not distinguished from each other, they will be simply referred to as a “memory cell transistor MC”. Each of the memory cell transistors MC nonvolatilely stores data. The memory cell transistor MC includes a control gate and a charge storage layer. The select transistors ST1 and ST2 are switching elements. Each of the select transistors ST1 and ST2 is used to select a string unit SU in various operations.

In the NAND string NS, the memory cell transistors MC0 to MC7 are coupled in series. A drain of the select transistor ST1 is coupled to the bit line BL associated therewith. A source of the select transistor ST1 is coupled to one end of the memory cell transistors MC0 to MC7 coupled in series. A drain of the select transistor ST2 is coupled to the other end of the memory cell transistors MC0 to MC7 coupled in series. A source of the select transistor ST2 is coupled to a source line SL.

In the same block BLK, control gates of the memory cell transistors MC0 to MC7 are respectively coupled in common to word lines WL0 to WL7. Hereinafter, in a case where the word lines WL0 to WL7 are not distinguished from each other, they will be simply referred to as a “word line WL”. Gates of the select transistors ST1 in each of the string units SU0 to SU3 are respectively coupled in common to select gate lines SGD0 to SGD3. Hereinafter, in a case where the select gate lines SGD0 to SGD3 are not distinguished from each other, they will be simply referred to as a “select gate line SGD”. Gates of the select transistors ST2 included in the same block BLK are coupled in common to a select gate line SGS.

In the circuit configuration of the memory cell array 41 described above, the bit line BL is shared by the plurality of NAND strings NS assigned the same column address CA in the plurality of string units SU. The source line SL is shared by, for example, the plurality of blocks BLK.

A set of memory cell transistors MC coupled to a common word line WL in one string unit SU will be referred to, for example, as a cell unit CU. Each of the blocks BLK includes a plurality of cells units CU. Data stored in the cell unit CU including the plurality of memory cell transistors MC each adapted to store 1-bit data in accordance with a threshold voltage is equivalent to 1-page data. The cell unit CU may store 2-page data or more based on the number of bits stored in the memory cell transistors MC.

The circuit configuration of the memory cell array 41 is not limited to the configuration described in the above. For example, the number of string units SU in each block BLK and the number of memory cell transistors MC and select transistors ST1 and ST2 in each NAND string NS may be set freely.

### 1.1.3.2 Configuration of Memory Controller

An inner configuration of the memory controller 50 will be described with again FIG. 3. As shown in FIG. 3, the memory controller 50 includes, for example, a host interface (I/F) circuit 51, a CPU 52, a ROM 53, a RAM 54, a temperature sensor 55, a comparison circuit 56, a detection circuit 57, a generation circuit 61, and a memory interface (I/F) circuit 62.

The host interface circuit 51 is a circuit configured to control communications between the memory controller 50 and the host 2. The host interface circuit 51 is coupled to the host 2 via the host bus HB.

The CPU 52 is a control circuit of the memory controller 50. The CPU 52 controls the overall operation of the memory controller 50 by executing a program (firmware) stored in the ROM 53. For example, upon receipt of a write request from the host 2, the CPU 52 controls a write operation based on the received write request. Similar processing is performed in a read operation and an erase operation. Furthermore, the CPU 52 executes a defective temperature sensor detection operation. The defective temperature sensor detection operation is an operation that detects a defect in the temperature sensor 35 of each NAND chip CP and rewrites the temperature sensor data Temp of the NAND chip in which a detection of the temperature sensor 35 has been detected. The defective temperature sensor detection operation includes, for example, temperature sensor data acquisition processing, comparison processing, detection processing, replacement temperature data generation processing, and temperature information setting processing. The defective temperature sensor detection operation will be described later in detail.

The ROM 53 is a nonvolatile memory. The ROM 53 is, for example, an electrically erasable programmable read-only memory (EEPROM™). The ROM 53 stores programs such as firmware.

The RAM 54 is a volatile memory. The RAM 54 is, for example, an SRAM. The RAM 54 is used as a work area of the CPU 52. The RAM 54 stores firmware to manage the nonvolatile memory 30, and various types of management information.

The temperature sensor 55 measures a temperature of the memory controller 50. The temperature sensor 55 is a temperature measurement circuit that is prepared by applying, for example, a band gap reference circuit, etc., and is mounted inside the memory controller 50. Other examples of the temperature sensor 55 include a thermocouple. For example, the temperature sensor 55 measures a temperature of the CPU 52 inside the memory controller 50. The temperature sensor 55 may not directly measure a temperature of the CPU 52. The temperature sensor 55 may measure a temperature of, for example, a portion other than the CPU 52 inside the memory controller 50. Hereinafter, the temperature data measured by the temperature sensor 55 will be referred to as “temperature sensor data TempC”.

The comparison circuit 56 is a circuit configured to perform comparison processing. The comparison circuit 56 will be described later in detail.

The detection circuit 57 is a circuit configured to perform detection processing. The detection circuit 57 will be described later in detail.

The generation circuit 61 is a circuit configured to perform replacement temperature data generation processing. The generation circuit 61 will be described later in detail.

The memory interface circuit 62 is a circuit configured to manage communications between the memory controller 50 and the nonvolatile memory 30. The memory interface circuit 62 is coupled to the nonvolatile memory 30 via the memory bus MB. For example, the memory interface circuit 62 controls transfer of data, commands, addresses, etc., between the memory controller 50 and the nonvolatile memory 30.

### 1.1.4 Structure of Memory System

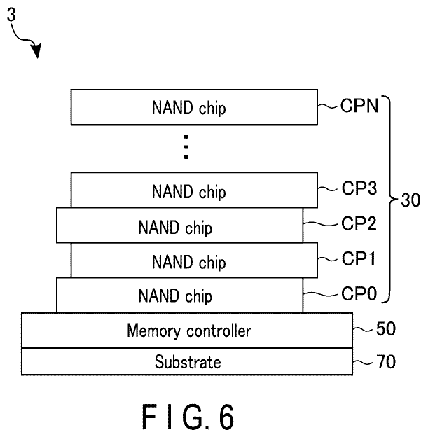

The structure of the memory system 3 will be described with reference to FIG. 6. FIG. 6 is a cross-sectional view showing an example of the structure of the memory system 3. FIG. 6 omits illustration of the memory bus MB.

As shown in FIG. 6, the memory controller 50 is provided on a substrate 70. On the memory controller 50, (N+1) NAND chips CP are stacked in the order of the NAND chips CP0, CP1, CP2, CP3, . . . , CPN from the side close to the substrate 70.

In the memory system 3 that has the structure as described above, a respective one of NAND chip CP is in contact with one or two other NAND chips in the nonvolatile memory 30. Therefore, a value of the temperature sensor data Temp of the temperature sensor 35 is approximately equal between the NAND chips CP.

### 1.1.5 Configuration of Temperature Sensor

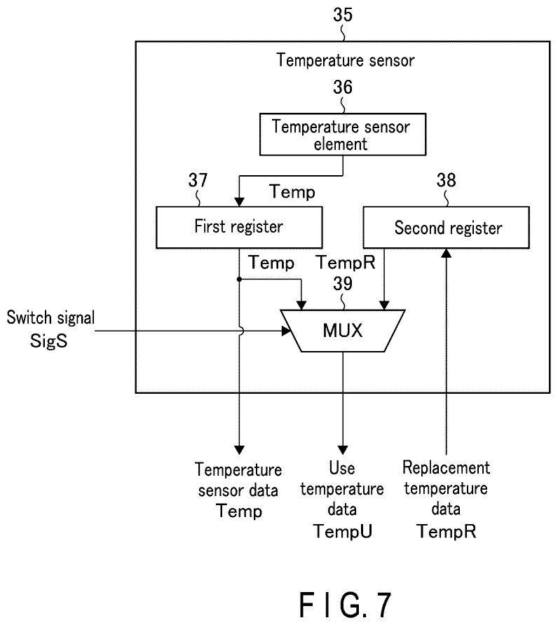

A configuration of the temperature sensor 35 of the NAND chip CP will be described with reference to FIG. 7. FIG. 7 is a circuit diagram showing an example of the configuration of the temperature sensor 35. As shown in FIG. 7, the temperature sensor 35 includes a temperature sensor element 36, a first register 37, a second register 38, and a multiplexer (MUX) 39.

The temperature sensor element 36 measures a temperature. The temperature sensor element 36 transmits the measured temperature sensor data Temp to the first register 37.

The first register 37 is a circuit configured to temporarily store the temperature sensor data Temp measured by the temperature sensor element 36. The first register 37 receives the temperature sensor data Temp from the temperature sensor element 36. The first register 37 stores the received temperature sensor data Temp. The first register 37 outputs the stored temperature sensor data Temp to an outside of the temperature sensor 35 and also transmits it to the MUX 39. The temperature sensor data Temp output to the outside of the temperature sensor 35 is transmitted to the sequencer 40.

The second register 38 is a circuit configured to temporarily store the replacement temperature data TempR set for the first feature register 34d. The second register 38 receives the replacement temperature data TempR from the first feature register 34d. The second register 38 stores the received replacement temperature data TempR. The second register 38 transmits the stored replacement temperature data TempR to the MUX 39.

The MUX 39 is a circuit configured to select, based on the switch signal SigS set for the first feature register 34d, either the temperature sensor data Temp stored in the first register 37 or the replacement temperature data TempR stored in the second register 38 and output the selected data.

The MUX 39 receives the switch signal SigS from the first feature register 34d. For example, the switch signal SigS is a value of either “0” or “1”. This description defines “0” as a value indicating that the temperature sensor data Temp is not to be replaced (indicating (a state of) the temperature sensor 35 being not defective), and “1” as a value indicating that the temperature sensor data Temp is to be replaced (indicating (a state of) the temperature sensor 35 being defective). Meanwhile, values of the switch signal SigS are not necessarily defined in this way. The MUX 39 receives the temperature sensor data Temp from the first register 37. The MUX 39 receives the replacement temperature data TempR from the second register 38. The MUX 39 outputs the selected temperature data as the use temperature data TempU to the outside of the temperature sensor 35 based on the switch signal SigS. In a case where the switch signal SigS is equal to “0”, the MUX 39 outputs the temperature sensor data Temp as the use temperature data TempU. On the other hand, in a case where the switch signal SigS is equal to “1”, the MUX 39 outputs the replacement temperature data TempR as the use temperature data TempU. As described above, the NAND chip CP (temperature sensor 35) switches the use temperature data TempU based on the switch signal SigS. The use temperature data TempU output to the outside of the temperature sensor 35 is transmitted to the second feature register 34e.

The temperature sensor 35 may not include the first register 37 and the second register 38. In this case, for example, the temperature sensor data Temp measured by the temperature sensor element 36 is output to the outside of the temperature sensor 35 and is also transmitted to the MUX 39. The replacement temperature data TempR input from the outside of the temperature sensor 35 is transmitted to the MUX 39.

### 1.1.6 Configuration of Comparison Circuit

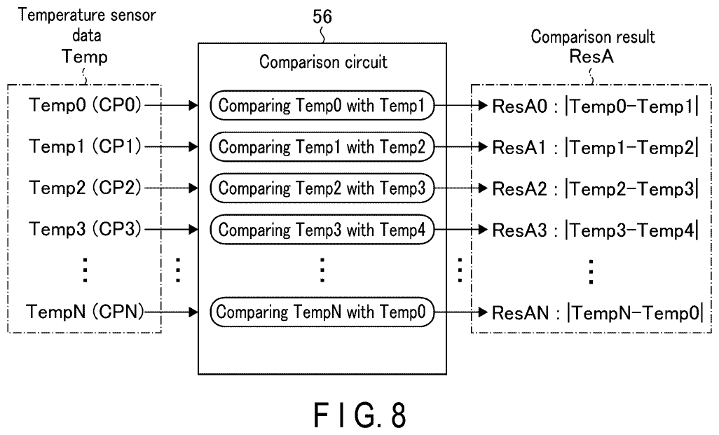

The configuration of the comparison circuit 56 of the memory controller 50 will be described with reference to FIG. 8. FIG. 8 is a diagram illustrating an example of the configuration of the comparison circuit 56.

As shown in FIG. 8, the comparison circuit 56 receives the temperature sensor data Temp from each of the NAND chips CP0 to CPN. The temperature sensor data Temp includes temperature sensor data Temp0 to TempN. The temperature sensor data Temp0 to TempN respectively correspond to the NAND chips CP0 to CPN.

For each of the NAND chips CP, the comparison circuit 56 makes a comparison of temperature sensor data Temp between a NAND chip CP concerned and one NAND chip CP adjacent to the NAND chip CP concerned. Herein, “one NAND chip CP adjacent the NAND chip CP concerned” indicates one NAND chip CP arranged in a manner so as to be physically adjacent to the NAND chip CP concerned, and is defined as described below, for example.

In the present embodiment, as shown in FIG. 6, the NAND chip CP1 is provided on the NAND chip CP0. Thus, one NAND chip CP adjacent to the NAND chip CP0 is defined as the NAND chip CP1. The NAND chip CP2 is provided on the NAND chip CP1. Thus, one NAND chip CP adjacent to the NAND chip CP1 is defined as the NAND chip CP2. The NAND chip CP3 is provided on the NAND chip CP2. Thus, one NAND chip CP adjacent to the NAND chip CP2 is defined as the NAND chip CP3. The subsequent NAND chips CP are defined in a similar manner. Meanwhile, no NAND chip CP is provided on the NAND chip CPN. Thus, one NAND chip CP adjacent to the NAND chip CPN is defined as the NAND chip CP0.

Based on the above definition, as shown in FIG. 8, the comparison circuit 56 makes a comparison between Temp0 and Temp1, a comparison between Temp1 and Temp2, a comparison between Temp2 and Temp3, a comparison between Temp3 and Temp4, . . . , a comparison between TempN and Temp0. As described above, the comparison circuit 56 makes a comparison between Temp0 and Temp1, and a comparison between Temp0 and TempN for the NAND chip CP0. The comparison circuit 56 makes a comparison for the other NAND chips CP in a similar manner.

The comparison circuit 56 calculates an absolute value of a difference between the compared temperature sensor data, and outputs the calculated value (a result of the comparison) as a comparison result ResA. The comparison result ResA includes (N+1) comparison results ResA0 to ResAN. The comparison results ResA0 to ResAN correspond to an absolute value of a difference between Temp0 and Temp1, an absolute value of a difference between Temp1 and Temp2, an absolute value of a difference between Temp2 and Temp3, an absolute value of a difference between Temp3 and Temp4, . . . , and an absolute value of a difference between TempN and Temp0, respectively. The comparison result ResA output from the comparison circuit 56 is transmitted to the detection circuit 57.

### 1.1.7 Configuration of Detection Circuit

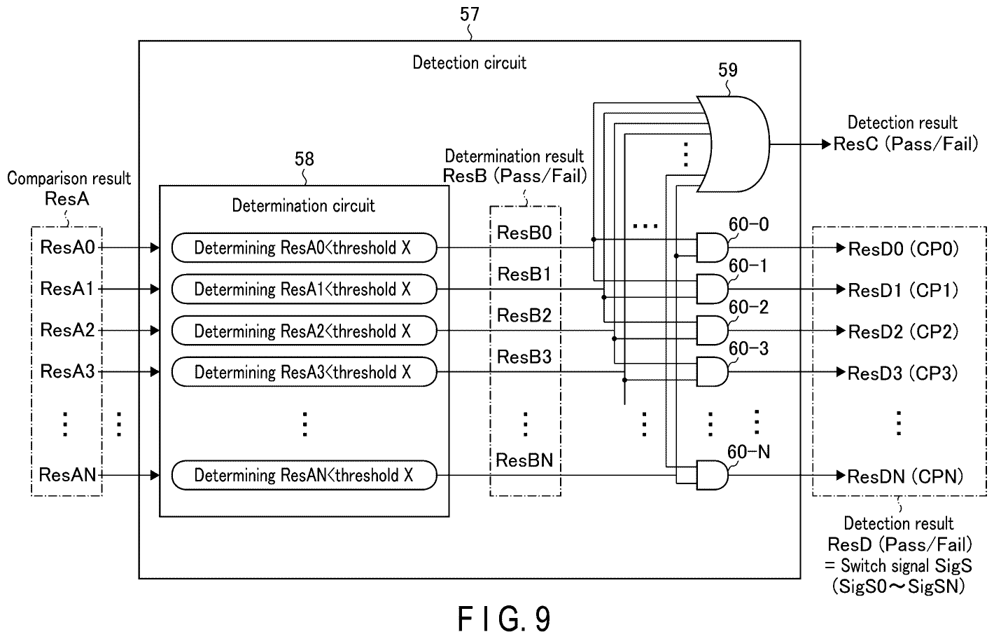

A configuration of the detection circuit 57 of the memory controller 50 will be described with reference to FIG. 9. FIG. 9 is a circuit diagram showing an example of the configuration of the detection circuit 57. As shown in FIG. 9, the detection circuit 57 includes a determination circuit 58, an OR circuit 59, and a plurality of AND circuits 60-0 to 60-N.

The determination circuit 58 receives (N+1) comparison results ResA0 to ResAN from the comparison circuit 56.

The determination circuit 58 makes a determination for each comparison result ResA as to whether a comparison result ResA concerned is smaller or not than a threshold X. In a case where the comparison result ResA concerned is smaller than the threshold X, the determination circuit 58 determines “Pass”, that is, determines that no defect in the temperature sensor 35 has occurred in both of two NAND chips CP serving as a calculation source for the comparison result ResA. On the other hand, in a case where the comparison result ResA concerned is equal to or greater than the threshold X, the determination circuit 58 determines “Fail”, that is, determines that a defect in the temperature sensor 35 has occurred in one of two NAND chips CP serving as a calculation source for the comparison result ResA. The reason for this is as follows. In the nonvolatile memory 30, as described above, a value of the temperature sensor data Temp is approximately equal between the NAND chips CP. Thus, in a case where a specific comparison result ResA is comparatively greater than the other comparison results ResA, it is assumed that a defect in the temperature sensor 35 is highly likely to occur in one of two NAND chips CP serving as a calculation source for the specific comparison result ResA.

The threshold X is a temperature determined in advice. For example, a product is operated on a trial basis before shipment, and a variation in the temperature sensor data Temp at the time of each NAND chip CP operating normally within a range of temperature guaranteed by the product is collected. The threshold X is determined based on the collected variation.

The determination circuit 58 outputs a result of the determination (Pass/Fail) as a determination result ResB. The determination result ResB includes (N+1) determination results ResB0 to ResBN. The determination results ResB0 to ResBN respectively correspond to a determination result regarding ResA0, a determination result regarding ResA1, a determination result regarding ResA2, a determination result regarding ResA3, . . . , and a determination result regarding ResAN. For example, the determination result ResB is a value of either “0” or “1”. Throughout this description, “0” is a value indicative of “Pass” and “1” is a value indicative of “Fail”. Meanwhile, values of the determination result ResB are not necessarily defined in this way.

(N+1) determination results ResB0 to ResBN are input from the determination circuit 58 to the OR circuit 59. The OR circuit 59 executes OR operations for the (N+1) determination results ResB0 to ResBN input thereto. The OR circuit 59 outputs a result of the OR operation (Pass/Fail) as a detection result ResC. The detection result ResC being equal to “0” indicates that there is no NAND chip CP in which a defect in the temperature sensor 35 has occurred in the nonvolatile memory 30. On the other hand, the detection result ResC being equal to “1” indicates that there is a NAND chip CP in which a defect in the temperature sensor 35 has occurred in the nonvolatile memory 30. The detection result ResC output from the OR circuit 59 is transmitted to the host 2.

The determination results ResBN and ResB0 are input from the determination circuit 58 to the AND circuit 60-0. The determination results ResB0 and ResB1 are input from the determination circuit 58 to the AND circuit 60-1. The determination results ResB1 and ResB2 are input from the determination circuit 58 to the AND circuit 60-2. The determination results ResB2 and ResB3 are input from the determination circuit 58 to the AND circuit 60-3. The same applies to the AND circuits 60-4 to 60-(N−1). The determination results ResB(N−1) and ResBN are input from the determination circuit 58 to the AND circuit 60-N.

Each of the AND circuits 60-0 to 60-N executes AND operations for two determination results ResB input thereto. Each of the AND circuits 60-0 to 60-N outputs a result of the AND operation (Pass/Fail) as a detection result ResD. The detection result ResD includes (N+1) detection results ResD0 to ResDN. The detection results ResD0 to ResDN respectively correspond to a result of the AND operation by the AND circuit 60-0, a result of the AND operation by the AND circuit 60-1, a result of the AND operation by the AND circuit 60-2, a result of the AND operation by the AND circuit 60-3, . . . , and a result of the AND operation by the AND circuit 60-N. Furthermore, the detection results ResD0 to ResDN respectively correspond to the NAND chip CP0 to the NAND chip CPN. The detection result ResD being equal to “0” indicates that no defect in the temperature sensor 35 has occurred in the corresponding NAND chip CP. On the other hand, the detection result ResD being equal to “1” indicates that a defect in the temperature sensor 35 has occurred in the corresponding NAND chip CP. As described above, the AND circuit 60-0 performs detection of a defect in the temperature sensor 35 of the NAND chip CP0 based on the determination results ResB0 and ResBN. Similarly, the other AND circuits 60-1 to 60-N perform detection of a defect in the temperature sensor 35 of the corresponding NAND chip CP. The detection results ResD0 to ResDN respectively output from the AND circuits 60-0 to 60-N are respectively transmitted as a switch signal SigS to the corresponding NAND chips CP.

### 1.1.8 Configuration of Generation Circuit

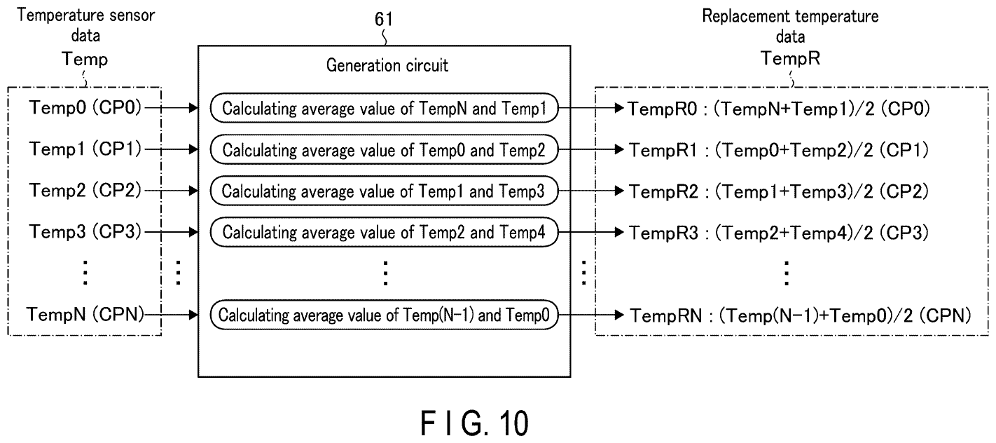

A configuration of the generation circuit 61 of the memory controller 50 will be described with reference to FIG. 10. FIG. 10 is a diagram illustrating an example of the configuration of the generation circuit 61.

As shown in FIG. 10, the generation circuit 61 receives the temperature sensor data Temp from each of the NAND chips CP0 to CPN. The temperature sensor data Temp includes (N+1) temperature sensor data Temp0 to TempN. The temperature sensor data Temp0 to TempN respectively correspond to the NAND chips CP0 to CPN.

For each of the NAND chips CP, the generation circuit 61 calculates an average value of two NAND chips CP adjacent to the NAND chip CP concerned. Herein, “two NAND chips CP adjacent to the NAND chip concerned” indicates two NAND chips CP arranged in a manner as to be physically adjacent to the NAND chip CP concerned, and are defined as described below, for example.

In the present embodiment, as shown in FIG. 6, the NAND chip CP1 is provided between the NAND chip CP0 and the NAND chip CP2. Thus, two NAND chips CP adjacent to the NAND chip CP1 are defined as the NAND chip CP0 and the NAND chip CP2. The NAND chip CP2 is provided between the NAND chips CP1 and CP3. Thus, two NAND chips CP adjacent to the NAND chip CP2 are defined as the NAND chip CP1 and the NAND chip CP3. The subsequent NAND chips CP are defined in a similar manner. Meanwhile, no NAND chip CP is provided below the NAND chip CP0. Thus, two NAND chips CP adjacent to the NAND chip CP0 are defined as the NAND chip CPN and the NAND chip CP1. No NAND chip CP is provided on the NAND chip CPN. Thus, two NAND chips CP adjacent to the NAND chip CPN are defined as the NAND chip CP(N−1) and the NAND chip CP0.

Based on the above definition, as shown in FIG. 10, the generation circuit 61 calculates an average value of TempN and Temp1, an average value of Temp0 and Temp2, an average value of Temp1 and Temp3, an average value of Temp2 and Temp4, . . . , and an average value of Temp(N−1) and Temp0.

The generation circuit 61 outputs a calculated average value as the replacement temperature data TempR. The replacement temperature data TempR includes (N+1) replacement temperature data TempR0 to TempRN. The replacement temperature data TempR0 to TempRN respectively correspond to an average value of TempN and Temp1, an average value of Temp0 and Temp2, an average value of Temp1 and Temp3, an average value of Temp2 and Temp4, . . . , an average value of Temp(N−1) and Temp0. The replacement temperature data TempR0 to TempRN respectively correspond to the NAND chips CP0 to CPN. As described above, the generation circuit 61 generates, for the NAND chip CP0, the corresponding replacement temperature data TempR0 based on TempN and Temp1. The generation circuit 61 generates the corresponding replacement temperature data TempR for the other NAND chips CP in a similar manner. The replacement temperature data TempR0 to TempRN output from the generation circuit 61 are respectively transmitted to the corresponding NAND chips CP.

### 1.2 Operation

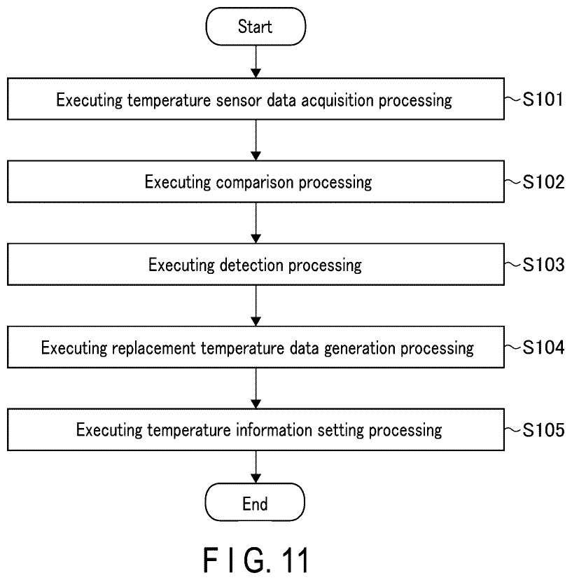

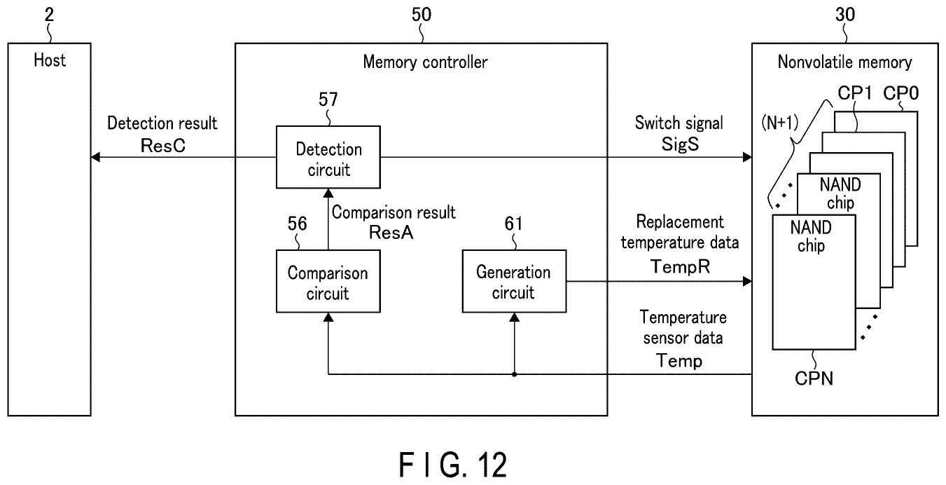

A defective temperature sensor detection operation of the information processing system 1 according to the first embodiment will be described with reference to FIG. 11 and FIG. 12. FIG. 11 is a flowchart showing an example of the defective temperature sensor detection operation in the information processing system 1 according to the first embodiment. FIG. 12 is a diagram illustrating an example of the defective temperature sensor detection operation in the information processing system 1 according to the first embodiment.

First, the memory controller 50 executes temperature sensor data acquisition processing at a predetermined interval (for example, one second, but not limited to one second) or at a given time (for example, a time when the command CMD is issued for the NAND chip CP) (S101). Specifically, for example, the CPU 52 issues a command set (hereinafter referred to as a “first command set CMDS1”) for reading the status information STS, and transmits the first command set CMDS1 to each NAND chip CP inside the nonvolatile memory 30. The first command set CMDS1 includes the command CMD and the address ADD. Each of the NAND chips CP receives the first command set CMDS1 from the memory controller 50. The sequencer 40 of each of the NAND chips CP acquires the temperature sensor data Temp from the temperature sensor 35 based on the command CMD within the first command set CMDS1, and transmits the temperature sensor data Temp as the status information STS to the memory controller 50. The CPU 52 receives the temperature sensor data Temp from each of the NAND chips CP and transmits the temperature sensor data Temp to the comparison circuit 56 and the generation circuit 61. By this, as shown in FIG. 12, the comparison circuit 56 and the generation circuit 61 receive the temperature sensor data Temp from each of the NAND chips CP. Examples of the predetermined interval include an interval that makes it possible to follow temperature fluctuation in the NAND chip CP since a temperature of the NAND chip CP fluctuate. Such an interval is, for example, one second, but is not limited to one second.

Next, the comparison circuit 56 executes comparison processing (S102). For example, the comparison circuit 56 makes a comparison of the temperature sensor data Temp as described above, and transmits the comparison result ResA to the detection circuit 57 as shown in FIG. 12.

Next, the detection circuit 57 executes detection processing (S103). For example, the detection circuit 57 performs detection of a defect in the temperature sensor 35 as described above, and transmits the detection result ResC to the host 2 as shown in FIG. 12. Furthermore, the detection circuit 57 transmits the detection result ResD to the CPU 52.

Next, the generation circuit 61 executes the replacement temperature data generation processing (S104). For example, the generation circuit 61 generates the replacement temperature data TempR as described above. Furthermore, the generation circuit 61 transmits the replacement temperature data TempR to the CPU 52.

Next, the memory controller 50 executes temperature information setting processing (S105). Specifically, for example, the CPU 52 issues a command set (hereinafter referred to as a “second command set CMDS2”) for setting various types of information, and transmits the second command set CMDS2 to each NAND chip CP inside the nonvolatile memory 30. The second command set CMDS2 includes the command CMD, the address ADD, the replacement temperature data TempR, and the switch signal SigS. By this, as shown in FIG. 12, the detection circuit 57 transmits the switch signal SigS to each of the NAND chips CP, and the generation circuit 61 transmits the replacement temperature data TempR to each of the NAND chips CP. Each of the NAND chips CP receives the second command set CMDS2 from the memory controller 50. The sequencer 40 of each of the NAND chips CP stores the replacement temperature data TempR and the switch signal SigS in the first feature register 34d of each of the NAND chips CP based on the command CMD within the second command set CMDS2.

Hereinafter, the description of the defective temperature sensor detection operation will be given based on an exemplary case in which the nonvolatile memory 30 includes four NAND chips CP0 to CP3 and a defect in the temperature sensor 35 occurs in the NAND chip CP1.

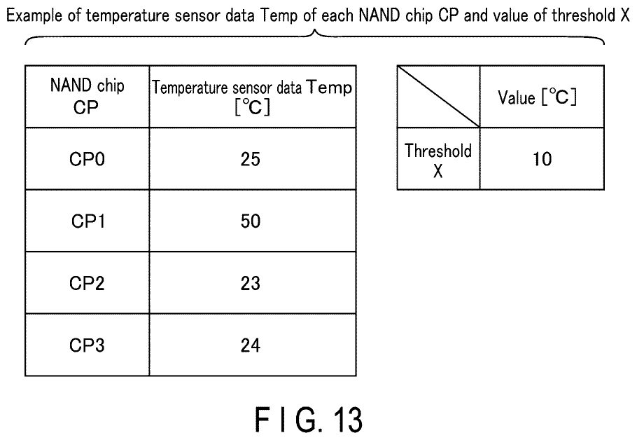

FIG. 13 is a diagram showing an example of the temperature sensor data Temp and the threshold X of each of the NAND chips in the information processing system 1 according to the first embodiment. As shown in FIG. 13, the temperature sensor data Temp exhibits approximately the same temperature between the NAND chips CP0, CP2, and CP3 in which no defect in the temperature sensor 35 has occurred. It is assumed that the temperature sensor data Temp0 of the NAND chip CP0 is 25° C. It is assumed that the temperature sensor data Temp2 of the NAND chip CP2 is 23° C. It is assumed that the temperature sensor data Temp3 of the NAND chip CP3 is 24° C. It is assumed that the temperature sensor data Temp1 of the NAND chip CP1 in which a defect in the temperature sensor 35 has occurred is 50° C. Temp1 is a temperature higher than Temp0, Temp2, and Temp3. It is assumed that the threshold X is 10° C.

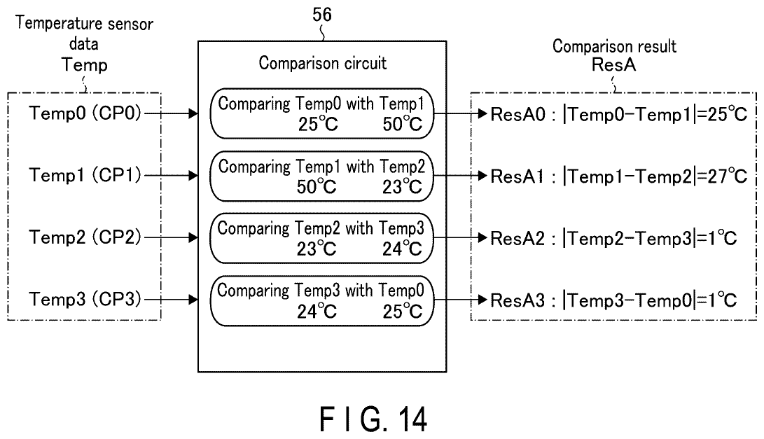

First, comparison processing will be described with reference to FIG. 14. FIG. 14 is a diagram illustrating an example of an operation of the comparison circuit 56. After execution of the temperature sensor data acquisition processing, as shown in FIG. 14, the comparison circuit 56 receives the temperature sensor data Temp0 to Temp3 from the NAND chips CP0 to CP3. The comparison circuit 56 compares Temp0 (25° C.) with Temp1 (50° C.) and outputs the absolute value (=25° C.) of the difference between Temp0 and Temp1 as the comparison result ResA0. The comparison circuit 56 compares Temp1 (50° C.) with Temp2 (23° C.) and outputs the absolute value (=27° C.) of the difference between Temp1 and Temp2 as the comparison result ResA1. The comparison circuit 56 compares Temp2 (23° C.) with Temp3 (24° C.) and outputs the absolute value (=1° C.) of the difference between Temp2 and Temp3 as the comparison result ResA2. The comparison circuit 56 compares Temp3 (24° C.) with Temp0 (25° C.) and outputs the absolute value (=1° C.) of the difference between Temp3 and Temp0 as the comparison result ResA3. The comparison results ResA0 to ResA3 are transmitted to the detection circuit 57.

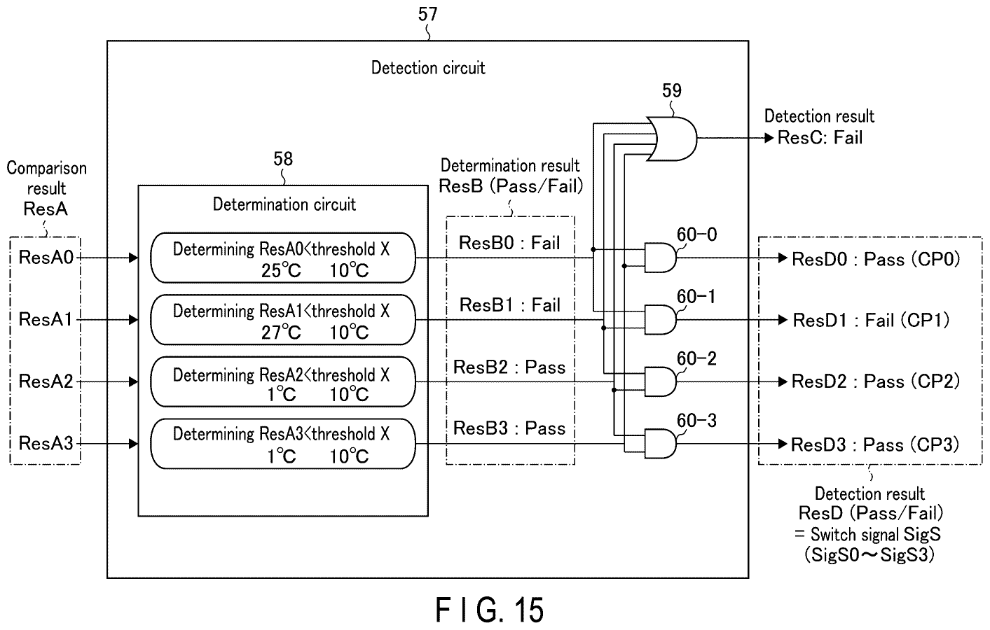

Next, detection processing will be described with reference to FIG. 15. FIG. 15 is a diagram illustrating an example of operation of the detection circuit 57.

As shown in FIG. 15, the detection circuit 57 receives the comparison results ResA0 to ResA3 from the comparison circuit 56. The determination circuit 58 makes a determination as to whether ResA0 (25° C.) is smaller than the threshold X (10° C.), and outputs a result of the determination (=Fail) as a determination result ResB0. The determination circuit 58 makes a determination as to whether ResA1 (27° C.) is smaller than the threshold X (10° C.), and outputs a result of the determination (=Fail) as a determination result ResB1. The determination circuit 58 makes a determination as to whether ResA2 (1° C.) is smaller than the threshold X (10° C.), and outputs a result of the determination (=Pass) as a determination result ResB2. The determination circuit 58 makes a determination as to whether ResA3 (1° C.) is smaller than the threshold X (10° C.), and outputs a result of the determination (=Pass) as a determination result ResB3.

The determination results ResB0 to ResB3 are input from the determination circuit 58 to the OR circuit 59. The OR circuit 59 executes an OR operation and outputs a result of the OR operation (=Fail) as the detection result ResC. The detection result ResC is transmitted to the host 2.

The determination results ResB3 and ResB0 are input from the determination circuit 58 to the AND circuit 60-0. The AND circuit 60-0 executes an AND operation and outputs a result of the AND operation (=Pass) as the detection result ResD0. The determination results ResB0 and ResB1 are input from the determination circuit 58 to the AND circuit 60-1. The AND circuit 60-1 executes an AND operation and outputs a result of the AND operation (=Fail) as the detection result ResD1. The determination results ResB1 and ResB2 are input from the determination circuit 58 to the AND circuit 60-2. The AND circuit 60-2 executes an AND operation and outputs a result of the AND operation (=Pass) as the detection result ResD2. The determination results ResB2 and ResB3 are input from the determination circuit 58 to the AND circuit 60-3. The AND circuit 60-3 executes an AND operation and outputs a result of the AND operation (=Pass) as the detection result ResD3. The detection results ResD0 to ResD3, that is, the switch signals SigS0 to SigS3 are respectively transmitted to the NAND chips CP0 to CP3 via the CPU 52.

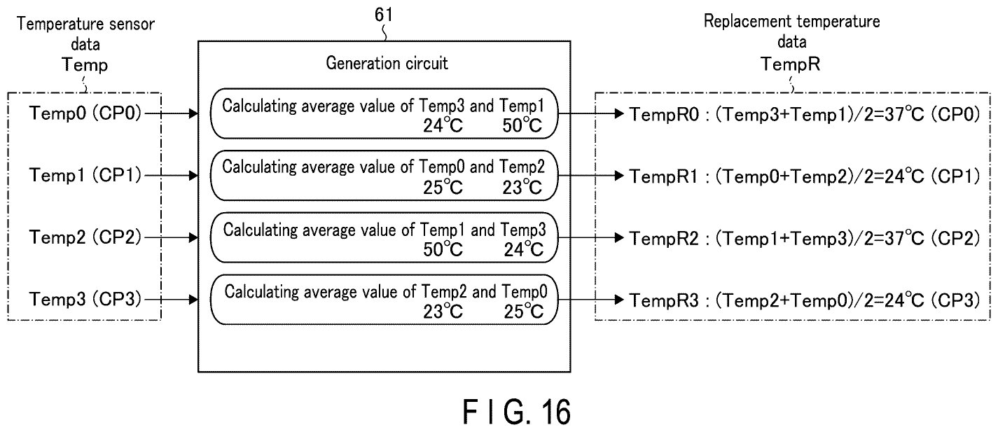

Next, replacement temperature data generation processing will be described with reference to FIG. 16. FIG. 16 is a diagram illustrating an example of operation of the generation circuit 61. As shown in FIG. 16, the generation circuit 61 receives the temperature sensor data Temp0 to Temp3 respectively from the NAND chips CP0 to CP3. The generation circuit 61 calculates an average value of Temp3 (24° C.) and Temp1 (50° C.), and outputs the average value (=37° C.) as the replacement temperature data TempR0. The generation circuit 61 calculates an average value of Temp0 (25° C.) and Temp2 (23° C.), and outputs the average value (=24° C.) as the replacement temperature data TempR1. The generation circuit 61 calculates an average value of Temp1 (50° C.) and Temp3 (24° C.), and outputs the average value (=37° C.) as the replacement temperature data TempR2. The generation circuit 61 calculates an average value of Temp2 (23° C.) and Temp0 (25° C.), and outputs the average value (=24° C.) as the replacement temperature data TempR3. The replacement temperature data TempR0 to TempR3 are respectively transmitted to the NAND chips CP0 to CP3 via the CPU 52.

By the temperature information setting processing being executed after execution of the replacement temperature data generation processing, the replacement temperature data TempR and the switch signal SigS are stored in the first feature register 34d of each of the NAND chips CP0 to CP3.

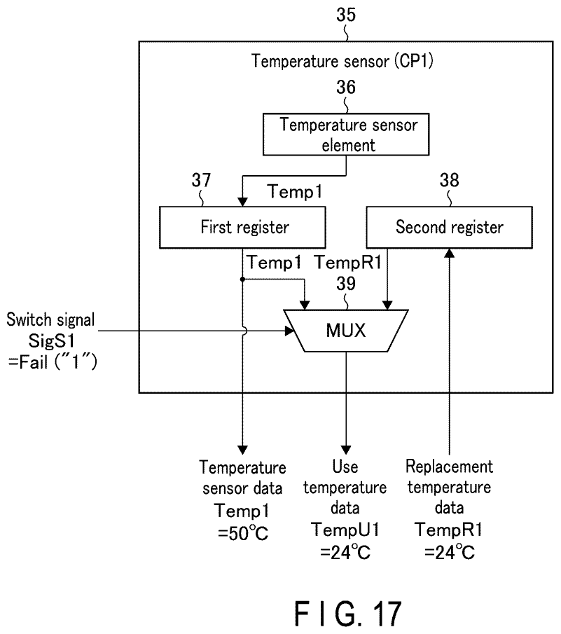

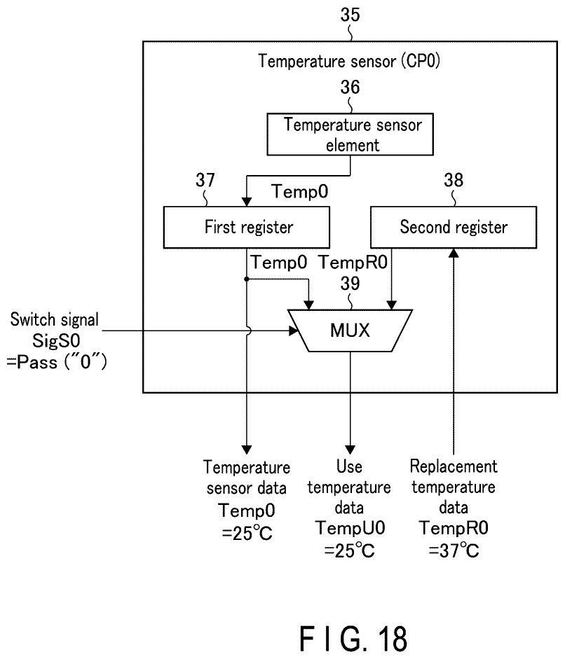

FIG. 17 and FIG. 18 are each a diagram illustrating an example of operation of the temperature sensor 35.

After execution of the temperature information setting processing, as shown in FIG. 17, the switch signal SigS1 (Fail(“1”)) is input from the first feature register 34d to the temperature sensor 35 of the NAND chip CP1. The replacement temperature data TempR1 (24° C.) is input from the first feature register 34d to the second register 38 of the temperature sensor 35 in the NAND chip CP1. The first register 37 of the temperature sensor 35 in the NAND chip CP1 outputs the temperature data (50° C.) stored in the first register 37, as the temperature sensor data Temp1. The MUX 39 of the temperature sensor 35 in the NAND chip CP1 outputs, based on the switch signal SigS1, the temperature data (24° C.) stored in the second register 38 to the use temperature data TempU1.

After execution of the temperature information setting processing, as shown in FIG. 18, the switch signal SigS0 (Pass(“0”)) is input from the first feature register 34d to the temperature sensor 35 in the NAND chip CP0. The replacement temperature data TempR0 (37° C.) is input from the first feature register 34d to the second register 38 of the temperature sensor 35 in the NAND chip CP0. The first register 37 of the temperature sensor 35 in the NAND chip CP0 outputs the temperature data (25° C.) stored in the first register 37, as the temperature sensor data Temp0. The MUX 39 of the temperature sensor 35 in the NAND chip CP0 outputs, based on the switch signal SigS0, the temperature data (25° C.) stored in the first register 37 to the use temperature data TempU0.

### 1.3 Advantageous Effect of First Embodiment

In the NAND chip, it becomes easier for electrons to flow through a channel of a memory cell transistor as a temperature of the NAND chip increases. Therefore, at the time of writing data, in the same write states, a voltage applied to a word line decreases as a temperature increases. Furthermore, at the time of reading data, a voltage applied to a word line, which is necessary for a current to flow through a bit line, decreases. Considering such temperature characteristics of a NAND chip, the NAND chip controls a voltage of a word line in write or read with reference to the temperature sensor data acquired from the temperature sensor mounted on the NAND chip.

However, even if a voltage of the word line is controlled as described above, in a case where the temperature sensor is defective and there is separation between the actual temperature of the NAND chip and the temperature sensor data measured by the temperature sensor in the NAND chip, data may not be written or read correctly.

In the memory system 3 according to the present embodiment, each of the NAND chips CP inside the nonvolatile memory 30 includes the first feature register 34d, the second feature register 34e, and the temperature sensor 35. The switch signal SigS and the replacement temperature data TempR input from an outside are stored in the first feature register 34d. The temperature sensor 35 switches, based on the switch signal SigS, the measured temperature sensor data Temp and the replacement temperature data TempR input from the outside, and outputs the switched data as the use temperature data TempU. The use temperature data TempU output from the temperature sensor 35 is stored in the second feature register 34e. As described above, in each of the NAND chip CP, the use temperature data TempU can be rewritten.

Furthermore, in the memory system 3 according to the present embodiment, the memory controller 50 includes the comparison circuit 56, the detection circuit 57, and the generation circuit 61. For each of the NAND chips CP, the comparison circuit 56 makes a comparison of temperature sensor data Temp between a NAND chip CP concerned (hereinafter also referred to as a “target NAND chip”) and one adjacent NAND chip CP, and outputs an absolute value of a difference between the compared temperature sensor data as the comparison result ResA. The detection circuit 57 makes a determination for each comparison result ResA as to whether a comparison result ResA concerned is smaller than the threshold X, and outputs, as the detection result ResD (switch signal SigS), an AND operation result of two determination results ResB relating to the target NAND chip CP. For each of the NAND chips CP, the generation circuit 61 outputs, as the replacement temperature data TempR, an average value of two NAND chips CP adjacent to a NAND chip CP concerned. As described above, in the nonvolatile memory 30, the temperature sensor data Temp is approximately equal between the NAND chips CP. Accordingly, a defect in the temperature sensor 35 can be detected appropriately, and the replacement temperature data TempR close to an actual temperature of the NAND chip CP can be generated. Meanwhile, in a case where comparison processing, detection processing, and replacement temperature data generation processing are performed using three NAND chips CP that are physically adjacent to each other (that are arranged at positions physically close to each other), a defect in the temperature sensor 35 can be detected more appropriately, and the replacement temperature data TempR closer to an actual temperature of the NAND chip CP can be generated. The switch signal SigS and the replacement temperature data TempR are transmitted from the memory controller 50 to the corresponding NAND chip CP, and are stored in the first feature register 34d of the corresponding NAND chip CP.

In the manner described above, the use temperature data TempU for use in the NAND chip CP in which the temperature sensor 35 is defective can be rewritten to more appropriate temperature data. The voltage generation circuit 42 controls a voltage of a word line in writing and in reading based on the use temperature data TempU stored in the second feature register 34e. In this manner, the accuracy of writing and reading of data can be improved. Thus, the semiconductor device 30, the memory system 3, and the information processing system 1 according to the present embodiment achieve an improvement of operation reliability.

Furthermore, the host 2 or the memory controller 50 uses a technique called thermal throttling, in which heat generation is suppressed by suppressing operation speed of a memory in a case where a temperature increases.

However, in a case where a defect in the temperature sensor causes the temperature sensor to output a temperature higher than an actual temperature, thermal slotting is executed even when it is not necessary, which may slow the operation of memory. Furthermore, in a case where a defect in the temperature sensor causes the temperature sensor to output a temperature lower than an actual temperature, thermal slotting may not be executed even when it is necessary.

In the memory system 3 according to the present embodiment, the detection circuit 57 outputs an OR operation result as the detection result ResC, for all of the determination results ResB. The detection result ResC is transmitted from the memory controller 50 to the host 2. This enables the memory controller 50 and the host 2 to detect whether or not there is a defect in the temperature sensor 35 of the NAND chip CP in the nonvolatile memory 30. Thus, the semiconductor device 30, the memory system 3, and the information processing system 1 according to the present embodiment can conduct thermal slotting appropriately.

### 1.4 First Modification

A configuration of an information processing system 1A according to a first modification of the first embodiment will be described. The information processing system 1A according to the present modification is different from that of the first embodiment in terms of the configuration of a nonvolatile memory 30A and the configurations of a comparison circuit 56A and a generation circuit 61A of a memory controller 50A. Hereinafter, the following description will in principle concentrate on the features different from the first embodiment.

### 1.4.1 Configuration of Nonvolatile Memory

The nonvolatile memory 30A includes one NAND chip CP0. A configuration of the NAND chip CP0 is similar to that shown in FIG. 4 described in the first embodiment.

### 1.4.2 Configuration of Comparison Circuit

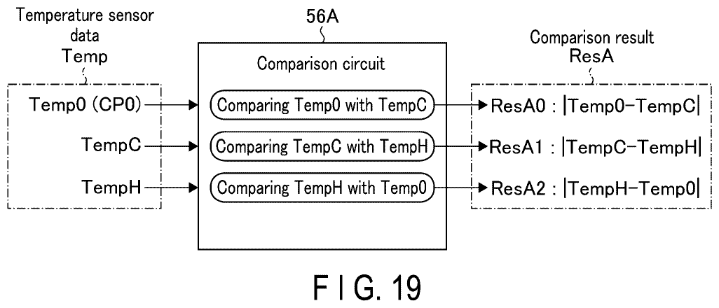

A configuration of the comparison circuit 56A will be described with reference to FIG. 19. FIG. 19 is a diagram illustrating an example of the configuration of the comparison circuit 56A.

As shown in FIG. 19, the comparison circuit 56A receives temperature sensor data Temp0 from the NAND chip CP0, receives temperature sensor data TempC from the temperature sensor 55, and receives temperature sensor data TempH from the temperature sensor 22 of the host 2.

As in the first embodiment, the comparison circuit 56A makes a comparison between Temp0 and TempC, a comparison between TempC and TempH, and a comparison between TempH and Temp0.

As in the first embodiment, the comparison circuit 56A calculates an absolute value of a difference between Temp0 and TempC, an absolute value of a difference between TempC and TempH, and an absolute value of a difference between TempH and Temp0, and outputs the calculated values as comparison results ResA0 to ResA2, respectively. The comparison results ResA0 to ResA2 output from the comparison circuit 56A are transmitted to the detection circuit 57.

### 1.4.3 Configuration of Generation Circuit

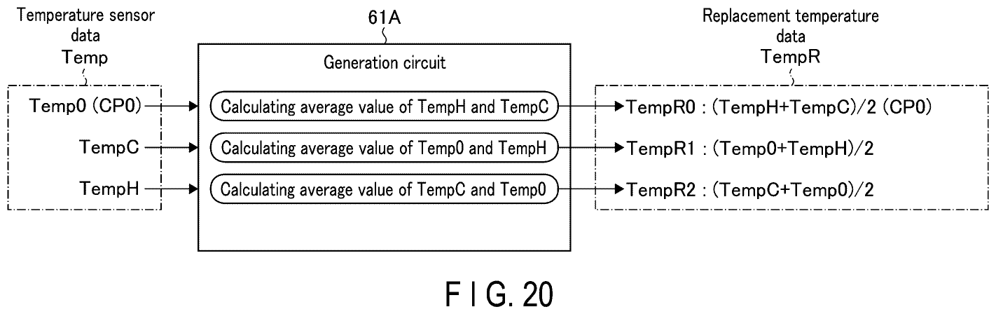

A configuration of the generation circuit 61A will be described with reference to FIG. 20. FIG. 20 is a diagram illustrating an example of a configuration of the generation circuit 61A.

As shown in FIG. 20, the generation circuit 61A receives the temperature sensor data Temp0 from the NAND chip CP0, receives the temperature sensor data TempC from the temperature sensor 55, and receives the temperature sensor data TempH from the temperature sensor 22 of the host 2.

As in the first embodiment, the generation circuit 61A calculates an average value of TempH and TempC, an average value of Temp0 and TempH, and an average value of TempC and Temp0, and outputs the calculated values as the replacement temperature data TempR0 to TempR2, respectively. The replacement temperature data TempR0 output from the generation circuit 61A is transmitted to the NAND chip CP0.

### 1.4.4 Operation

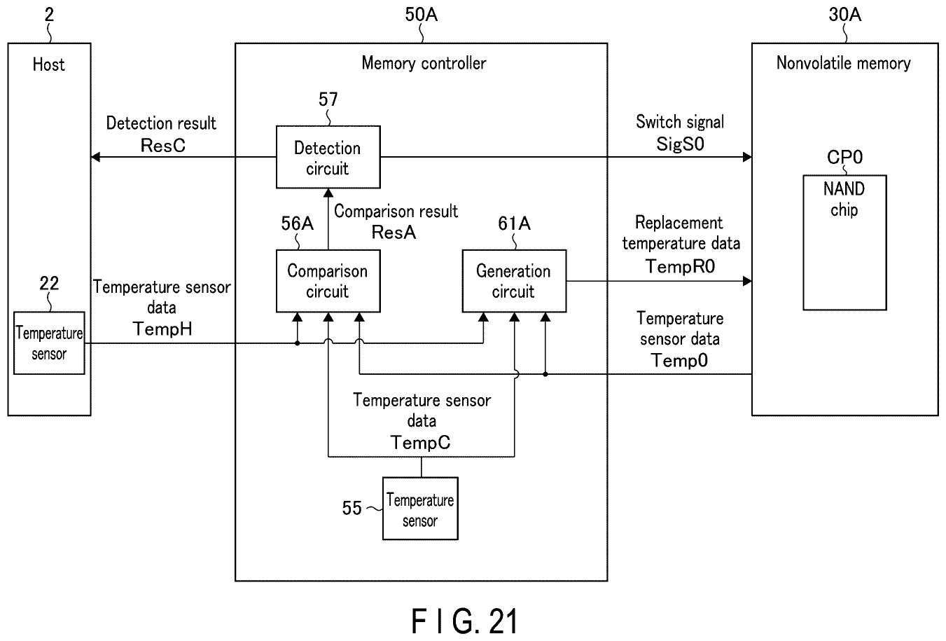

A defective temperature sensor detection operation of the information processing system 1A will be described with reference to FIG. 21. FIG. 21 is a diagram illustrating an example of the defective temperature sensor detection operation in the information processing system 1A. A flowchart showing an example of the defective temperature sensor detection operation in the information processing system 1A is similar to that shown in FIG. 11 described in the first embodiment.

In S101, the memory controller 50A executes temperature sensor data acquisition processing at a predetermined interval (for example, one second, but not limited to one second) or at a given time (for example, a time when the command CMD is issued for the NAND chip CP). Specifically, for example, the CPU 52 acquires the temperature sensor data Temp0 from the NAND chip CP0 as in the first embodiment. Furthermore, the CPU 52 acquires the temperature sensor data TempC from the temperature sensor 55 and acquires the temperature sensor data TempH from the temperature sensor 22 of the host 2. The CPU 52 transmits the temperature sensor data Temp0, TempC, and TempH to the comparison circuit 56A and the generation circuit 61A. By this, as shown in FIG. 21, the comparison circuits 56A and the generation circuit 61A receive the temperature sensor data Temp0 from the NAND chip CP0, receive the temperature sensor data TempC from the temperature sensor 55, and receive the temperature sensor data TempH from the host 2.

In S105, the memory controller 50A executes temperature information setting processing. Specifically, for example, the CPU 52 transmits the switch signal SigS0 received from the detection circuit 57, and the replacement temperature data tempR0 received from the generation circuit 61A to the NAND chip CP0, as in the first embodiment. By this, as shown in FIG. 21, the detection circuit 57 transmits the switch signal SigS0 to the NAND chip CP0, and the generation circuit 61A transmits the replacement temperature data TempR0 to the NAND chip CP0. The sequencer 40 of the NAND chip CP0 stores the replacement temperature data TempR0 and the switch signal SigS0 in the first feature register 34d of the NAND chip CP0, as in the first embodiment.

S102 to S104 are the same as those in the first embodiment.

### 1.4.5 Advantageous Effect of First Modification

In a memory system 3A according to the present modification, the comparison circuit 56A outputs an absolute value of a difference between the temperature sensor data Temp0 of the NAND chip CP0 and the temperature sensor data TempC of the temperature sensor 55, an absolute value of a difference between TempC and the temperature sensor data TempH of the temperature sensor 22, and an absolute value of a difference between TempH and Temp0, as comparison results ResA. The detection circuit 57 makes a determination for each of the comparison results ResA as to whether a comparison result ResA concerned is smaller than the threshold X, and outputs, as the detection result ResD0 (switch signal SigS0), an AND operation result of two determination results ResB relating to the NAND chip CP0. The generation circuit 61A outputs an average value of TempC and TempH as the replacement temperature data TempR0. Accordingly, the present modification produces advantageous effects similar to those of the first embodiment.

### 1.5 Second Modification

A configuration of an information processing system 1B according to a second modification of the first embodiment will be described. The information processing system 1B according to the present modification is different from that of the first embodiment in terms of the configuration of a nonvolatile memory 30B and the configurations of a comparison circuit 56B and a generation circuit 61B of a memory controller 50B. Hereinafter, the following description will in principle concentrate on the features different from the first embodiment.

### 1.5.1 Configuration of Nonvolatile Memory

The nonvolatile memory 30B includes two NAND chips CP0 and CP1. A configuration of each of the NAND chips CP0 and CP1 is similar to that shown in FIG. 4 described in the first embodiment.

### 1.5.2 Configuration of Comparison Circuit

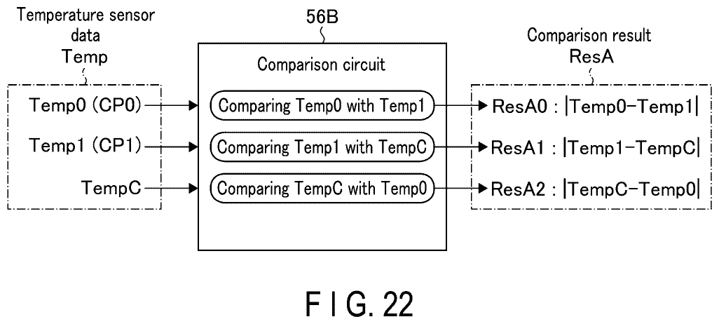

A configuration of the comparison circuit 56B will be described with reference to FIG. 22. FIG. 22 is a diagram illustrating an example of the configuration of the comparison circuit 56B.

As shown in FIG. 22, the comparison circuit 56B receives the temperature sensor data Temp0 from the NAND chip CP0, receives the temperature sensor data Temp1 from the NAND chip CP1, and receives the temperature sensor data TempC from the temperature sensor 55.

As in the first embodiment, the comparison circuit 56B makes a comparison between Temp0 and Temp1, a comparison between Temp1 and TempC, and a comparison between TempC and Temp0.

As in the first embodiment, the comparison circuit 56B calculates an absolute value of a difference between Temp0 and temp1, an absolute value of a difference between Temp1 and TempC, and an absolute value of a difference between TempC and Temp0, and outputs the calculated values as the comparison results ResA0 to ResA2, respectively. The comparison results ResA0 to ResA2 output from the comparison circuit 56B are transmitted to the detection circuit 57.

### 1.5.3 Configuration of Generation Circuit

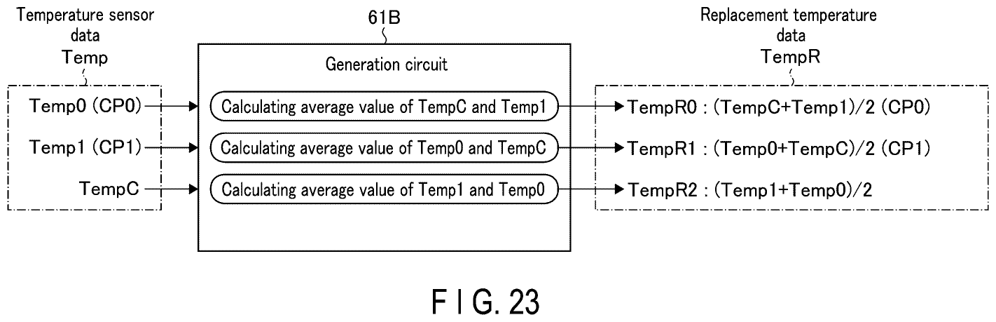

A configuration of the generation circuit 61B will be described with reference to FIG. 23. FIG. 23 is a diagram illustrating an example of a configuration of the generation circuit 61B.

As shown in FIG. 23, the generation circuit 61B receives the temperature sensor data Temp0 from the NAND chip CP0, receives the temperature sensor data Temp1 from the NAND chip CP1, and receives the temperature sensor data TempC from the temperature sensor 55.

As in the first embodiment, the generation circuit 61B calculates an average value of TempC and Temp1, an average value of Temp0 and TempC, and an average value of Temp1 and Temp0, and outputs the calculated values as the replacement temperature data TempR0 to TempR2, respectively. The replacement temperature data TempR0 output from the generation circuit 61B is transmitted to the NAND chip CP0. The replacement temperature data TempR1 output from the generation circuit 61B is transmitted to the NAND chip CP1.

### 1.5.4 Operation

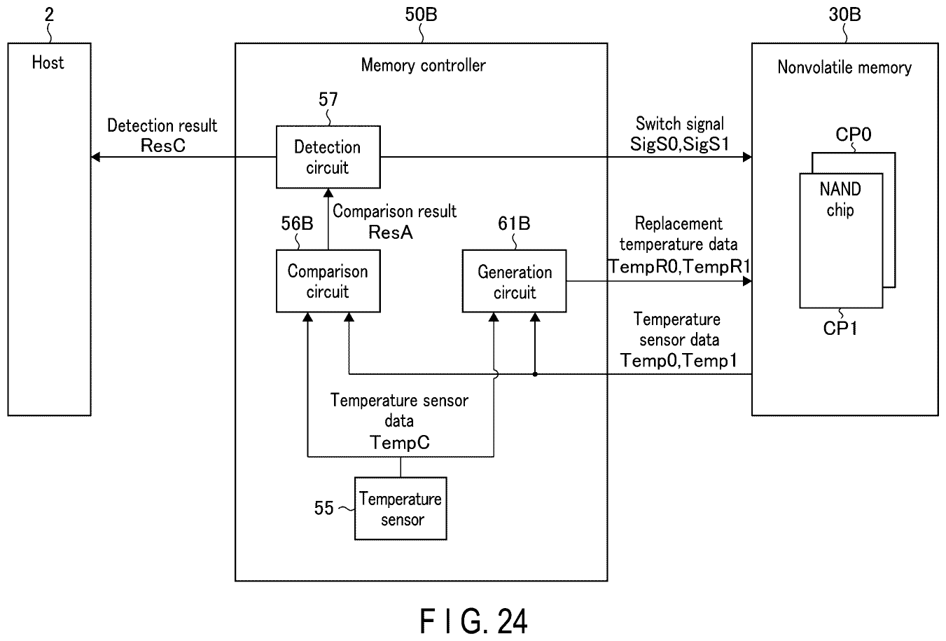

A defective temperature sensor detection operation of the information processing system 1B will be described with reference to FIG. 24. FIG. 24 is a diagram illustrating an example of the defective temperature sensor detection operation in the information processing system 1B. A flowchart showing an example of the defective temperature sensor detection operation in the information processing system 1B is similar to that shown in FIG. 11 described in the first embodiment.

In S101, the memory controller 50B executes temperature sensor data acquisition processing at a predetermined interval (for example, one second, but not limited to one second) or at a given time (for example, a time when the command CMD is issued for the NAND chip CP). Specifically, for example, the CPU 52 acquires the temperature sensor data Temp0 and Temp1 from the NAND chips CP0 and CP1, respectively, as in the first embodiment. The CPU 52 acquires the temperature sensor data TempC from the temperature sensor 55. The CPU 52 transmits the temperature sensor data Temp0, Temp1, and TempC to the comparison circuit 56B and the generation circuit 61B. By this, as shown in FIG. 24, the comparison circuit 56B and the generation circuit 61B receive the temperature sensor data Temp0 and Temp1 from the NAND chips CP0 and CP1, respectively, and receive the temperature sensor data TempC from the temperature sensor 55.

In S105, the memory controller 50B executes temperature information setting processing. Specifically, for example, the CPU 52 transmits the switch signals SigS0 and SigS1 received from the detection circuit 57, and the replacement temperature data tempR0 and TempR1 received from the generation circuit 61B to the NAND chips CP0 and CP1, respectively, as in the first embodiment. By this, as shown in FIG. 24, the detection circuit 57 transmits the switch signals SigS0 and SigS1 to the NAND chips CP0 and CP1, respectively, and the generation circuit 61B transmits the replacement temperature data TempR0 and TempR1 to the NAND chips CP0 and CP1, respectively. The sequencer 40 of the NAND chip CP0 stores the replacement temperature data TempR0 and the switch signal SigS0 in the first feature register 34d of the NAND chip CP0, as in the first embodiment. The sequencer 40 of the NAND chip CP1 stores the replacement temperature data TempR1 and the switch signal SigS1 in the first feature register 34d of the NAND chip CP1, as in the first embodiment.

S102 to S104 are the same as those in the first embodiment.

### 1.5.5 Advantageous Effect of Second Modification

In a memory system 3B according to the present modification, the comparison circuit 56B outputs an absolute value of a difference between the temperature sensor data Temp0 of the NAND chip CP0 and the temperature sensor data Temp1 of the NAND chip CP1, an absolute value of a difference between Temp1 and the temperature sensor data TempC of the temperature sensor 55, and an absolute value of a difference between TempC and Temp0, as comparison results ResA. The detection circuit 57 makes a determination for each comparison result ResA as to whether a comparison result ResA concerned is smaller or not than the threshold X. The detection circuit 57 outputs an AND operation result of two determination results ResB relating to the NAND chip CP0, and an AND operation result of two determination results ResB relating to the NAND chip CP1, as the detection results ResD0 and ResD1 (switch signals sigS0 and SigS1), respectively. The generation circuit 61B outputs an average value of TempC and Temp1 as the replacement temperature data TempR0, and outputs an average value of Temp0 and TempC as the replacement temperature data TempR1. Accordingly, the present modification produces advantageous effects similar to those of the first embodiment.

### 1.6 Third Modification

A configuration of an information processing system 1C according to the third modification of the first embodiment will be described. The information processing system 1C according to the present modification is different from that of the first embodiment in terms of the configuration of a generation circuit 61C of a memory controller 50C. Hereinafter, the following description will in principle concentrate on the features different from the first embodiment.

### 1.6.1 Configuration of Generation Circuit

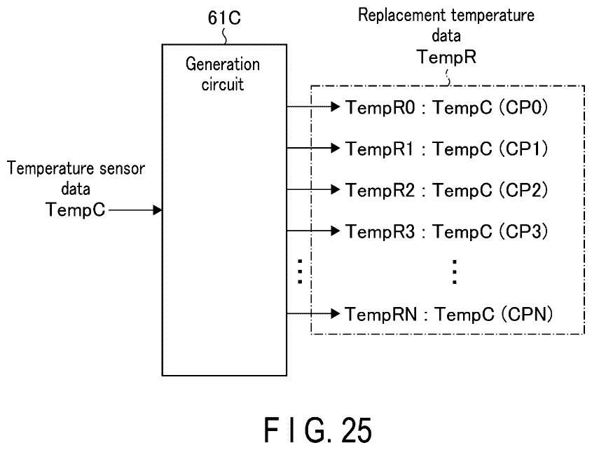

A configuration of the generation circuit 61C will be described with reference to FIG. 25. FIG. 25 is a diagram illustrating an example of a configuration of the generation circuit 61C.

As shown in FIG. 25, the generation circuit 61C receives the temperature sensor data TempC from the temperature sensor 55.

The generation circuit 61C outputs (generates) the temperature sensor data TempC as the replacement temperature data TempR0 to TempRN. The replacement temperature data TempR0 to TempRN output from the generation circuit 61C are respectively transmitted to the corresponding NAND chips CP.

### 1.6.2 Operation

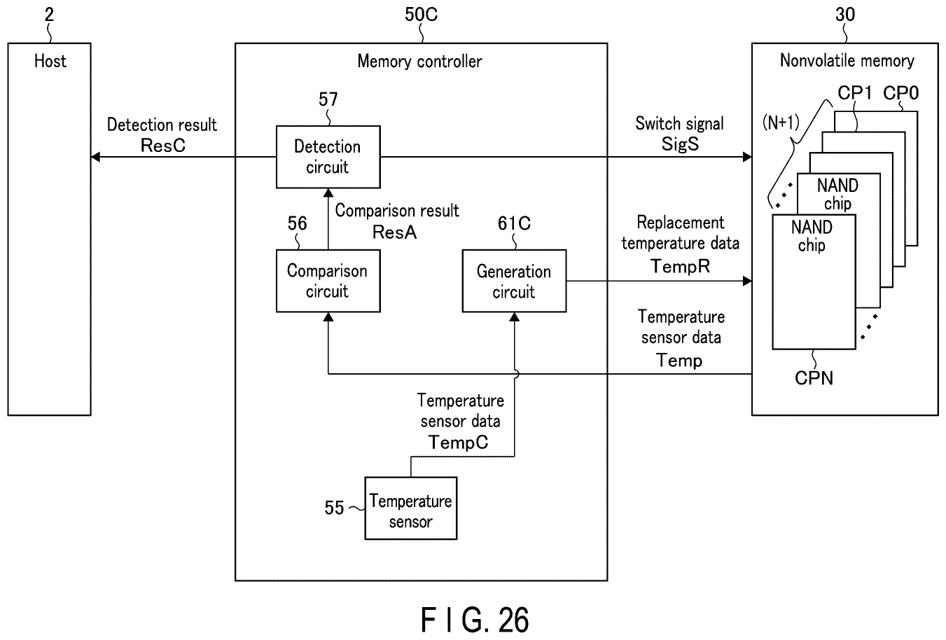

A defective temperature sensor detection operation of the information processing system 1C will be described with reference to FIG. 26. FIG. 26 is a diagram illustrating an example of the defective temperature sensor detection operation in the information processing system 1C. A flowchart showing an example of the defective temperature sensor detection operation in the information processing system 1C is similar to that shown in FIG. 11 described in the first embodiment.

In S101, the memory controller 50C executes temperature sensor data acquisition processing at a predetermined interval (for example, one second, but not limited to one second) or at a given time (for example, a time when the command CMD is issued for the NAND chip CP). Specifically, for example, the CPU 52 acquires the temperature sensor data Temp from each of the NAND chips CP as in the first embodiment. The CPU 52 acquires the temperature sensor data TempC from the temperature sensor 55. The CPU 52 transmits the temperature sensor data Temp to the comparison circuit 56 and transmits the temperature sensor data TempC to the generation circuit 61C. By this, as shown in FIG. 26, the comparison circuit 56 receives the temperature sensor data Temp from each NAND chip CP, and the generation circuit 61C receives the temperature sensor data TempC from the temperature sensor 55.

S102 to S105 are the same as those in the first embodiment.

### 1.6.3 Advantageous Effect of Third Modification

In the memory system 3C according to the present modification, the generation circuit 61C outputs the temperature sensor data TempC of the temperature sensor 55 as the replacement temperature data TempR. By this, the present modification produces advantageous effects similar to those of the first embodiment.

### 2. Second Embodiment

A configuration of an information processing system 1D according to a second embodiment will be described. The information processing system 1D according to the second embodiment is different from that of the first embodiment in terms of the configuration of a host 2D and a configuration of a memory controller 50D. Hereinafter, the following description will in principle concentrate on the features different from the first embodiment.

### 2.1 Configuration of Host

A hardware configuration of the host 2D is similar to that shown in FIG. 2 described in the first embodiment. The CPU 21 executes, for example, temperature sensor data acquisition processing, comparison processing, detection processing, replacement temperature data generation processing, and temperature information setting processing. The ROM 23 stores programs for causing the CPU 21 execute, for example, temperature sensor data acquisition processing, comparison processing, detection processing, replacement temperature data generation processing, and temperature information setting processing.

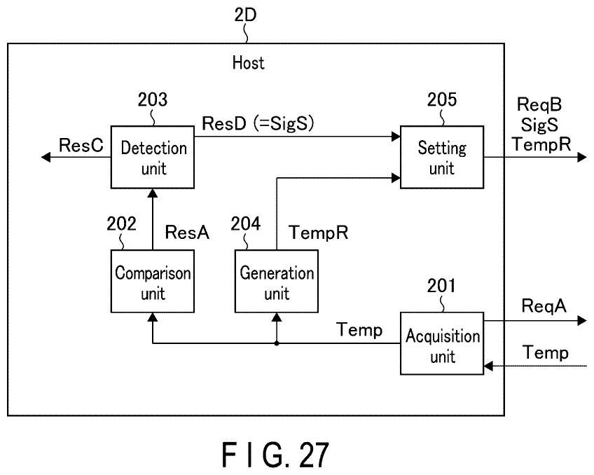

A functional configuration of the host 2D will be described with reference to FIG. 27. FIG. 27 is a block diagram showing an example of the functional configuration of the host 2D. As shown in FIG. 27, the host 2D includes an acquisition unit 201, a comparison unit 202, a detection unit 203, a generation unit 204, and a setting unit 205. The acquisition unit 201, the comparison unit 202, the detection unit 203, the generation unit 204, and the setting unit 205 are each a functional block corresponding to the CPU 21. That is, the CPU 21 functions as the acquisition unit 201, the comparison unit 202, the detection unit 203, the generation unit 204, and the setting unit 205. Meanwhile, FIG. 27 omits illustration of functional blocks corresponding to the temperature sensor 22, the ROM 23, the RAM 24, and the communication interface circuit 25.

The acquisition unit 201 performs the temperature sensor data acquisition processing. The temperature sensor data acquisition processing is processing to request the memory controller 50D to acquire the temperature sensor data Temp and to acquire the temperature sensor data Temp from each of the NAND chips CP in the nonvolatile memory 30. The acquisition unit 201 transmits a signal ReqA to request acquisition of the temperature sensor data Temp to the memory controller 50D and receives the temperature sensor data Temp of each NAND chip CP from the memory controller 50D. The acquisition unit 201 transmits the temperature sensor data Temp to the comparison unit 202 and the generation unit 204.

The comparison unit 202 performs comparison processing. The comparison processing is the same as that performed by the comparison circuit 56 described in the first embodiment. The comparison unit 202 receives the temperature sensor data Temp from the acquisition unit 201. The comparison unit 202 performs comparison processing based on the temperature sensor data Temp and transmits the comparison result ResA to the detection unit 203.

The detection unit 203 performs detection processing. The detection processing is the same as that performed by the detection circuit 57 described in the first embodiment. The detection unit 203 receives the comparison result ResA from the comparison unit 202. The detection unit 203 performs detection processing based on the comparison result ResA, outputs the detection result ResC, and transmits the detection result ResD, that is, the switch signal SigS, to the setting unit 205.

The generation unit 204 performs replacement temperature data generation processing. The replacement temperature data generation processing is the same as that performed by the generation circuit 61 described in the first embodiment. The generation unit 204 receives the temperature sensor data Temp from the acquisition unit 201. The generation unit 204 performs the replacement temperature data generation processing based on the temperature sensor data Temp and transmits the replacement temperature data TempR to the setting unit 205.

The setting unit 205 performs the temperature information setting processing. The temperature information setting processing is processing to request the memory controller 50D to set the temperature information and to set the temperature information for each of the NAND chips CP in the nonvolatile memory 30. The setting unit 205 receives the switch signal SigS from the detection unit 203. The setting unit 205 receives the replacement temperature data TempR from the generation unit 204. The setting unit 205 transmits a signal ReqB to request setting of the temperature information, the switch signal SigS, and the replacement temperature data TempR to the memory controller 50D.

### 2.2 Configuration of Memory Controller

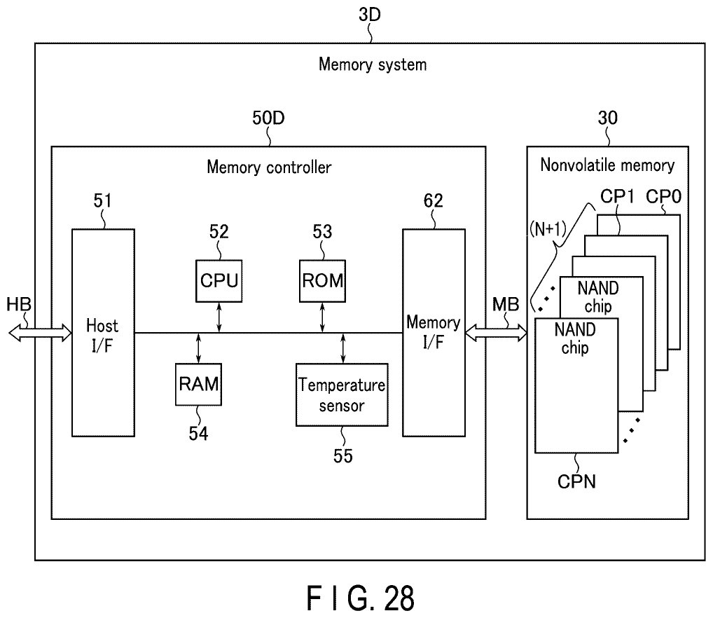

An internal configuration of the memory controller 50D will be described with reference to FIG. 28. FIG. 28 is a block diagram showing an example of a configuration of a memory system 3D. As shown in FIG. 28, the memory controller 50D includes, for example, the host interface circuit 51, the CPU 52, the ROM 53, the RAM 54, the temperature sensor 55, and the memory interface circuit 62. The comparison circuit 56, the detection circuit 57, and the generation circuit 61 each described in the first embodiment are eliminated from the memory controller 50D.

### 2.3 Operation

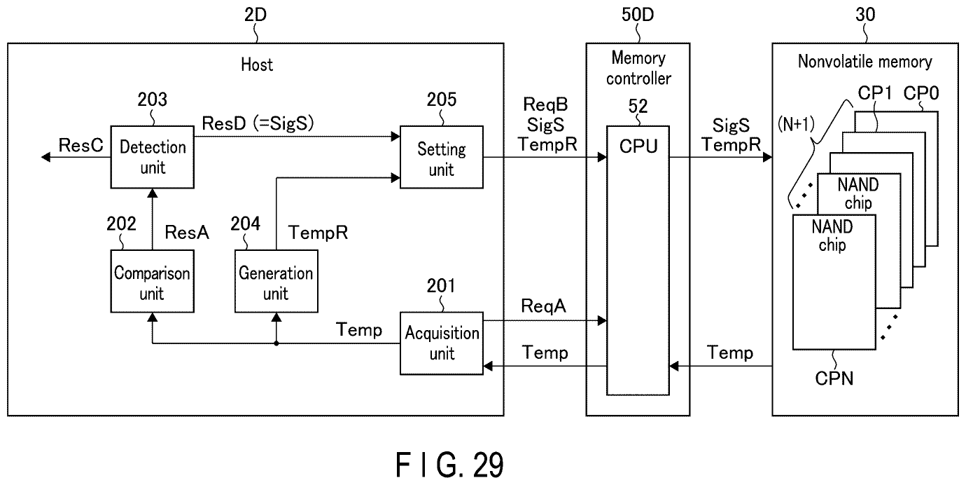

A defective temperature sensor detection operation of the information processing system 1D will be described with reference to FIG. 29. FIG. 29 is a diagram illustrating an example of the defective temperature sensor detection operation in the information processing system 1D. A flowchart showing an example of the defective temperature sensor detection operation in the information processing system 1D is similar to that shown in FIG. 11 described in the first embodiment.

In S101, the host 2D executes temperature sensor data acquisition processing at a predetermined interval (for example, one second, but not limited to one second) or at a given time (for example, a time when the command CMD is issued for the NAND chip CP). Specifically, for example, as shown in FIG. 29, the acquisition unit 201 transmits a signal ReqA to request acquisition of the temperature sensor data Temp to the memory controller 50D. In a case where the memory controller 50D receives the request signal ReqA, the CPU52 acquires the temperature sensor data Temp from each of the NAND chips CP as in the first embodiment. The CPU 52 transmits the temperature sensor data Temp of each of the NAND chips CP to the host 2D. The acquisition unit 201 receives the temperature sensor data Temp of each of the NAND chips CP from the memory controller 50D, and transmits the temperature sensor data Temp to the comparison unit 202 and the generation unit 204. By this, the comparison unit 202 and the generation unit 204 receive the temperature sensor data Temp from each of the NAND chips CP.

In S102, the comparison unit 202 performs comparison processing as in the first embodiment and transmits the comparison result ResA to the detection unit 203 as shown in FIG. 29.

In S103, the detection unit 203 performs detection processing as in the first embodiment and outputs the comparison result ResC as shown in FIG. 29. Furthermore, the detection unit 203 transmits the detection result ResD, that is, the switch signal SigS, to the setting unit 205.

In S104, the generation unit 204 performs the replacement temperature data generation processing as in the first embodiment, and transmits the replacement temperature data TempR to the setting unit 205, as shown in FIG. 29.

In S105, the host 2D executes temperature information setting processing. Specifically, for example, as shown in FIG. 29, the setting unit 205 transmits the signal ReqB to request setting of the temperature information, the switch signal SigS, and the replacement temperature data TempR to the memory controller 50D. In a case where the memory controller 50D receives the request signal ReqB, the switch signal SigS, and the replacement temperature data TempR, the CPU 52 transmits the switch signal SigS and the replacement temperature data TempR to each of the NAND chips CP as in the first embodiment. By this, the detection unit 203 transmits the switch signal SigS to each of the NAND chips CP, and the generation unit 204 transmits the replacement temperature data TempR to each of the NAND chips CP. The sequencer 40 of each NAND chip CP stores the replacement temperature data TempR and the switch signal SigS in the first feature register 34d of each NAND chip CP as in the first embodiment.

### 2.4 Advantageous Effect of Second Embodiment

The second embodiment produces the advantageous effects similar to those of the first embodiment.

Furthermore, according to the present embodiment, each processing of the defective temperature sensor detection operation can be implemented in software inside the host 2. This eliminates the need for mounting the comparison circuit 56, the detection circuit 57, and the generation circuit 61 on the memory controller 50. According to the present embodiment, the memory system 3D can be relatively decreased in physical size of a chip.

The first modification, the second modification, and the third modification of the first embodiment are applicable to the second embodiment.

### 3. Third Embodiment

A configuration of an information processing system 1E according to a third embodiment will be described. The information processing system 1E according to the third embodiment is different from that of the first embodiment in terms of the configuration of a memory system 3E. Hereinafter, the following description will in principle concentrate on the features different from the first embodiment.

### 3.1 Configuration of Memory System

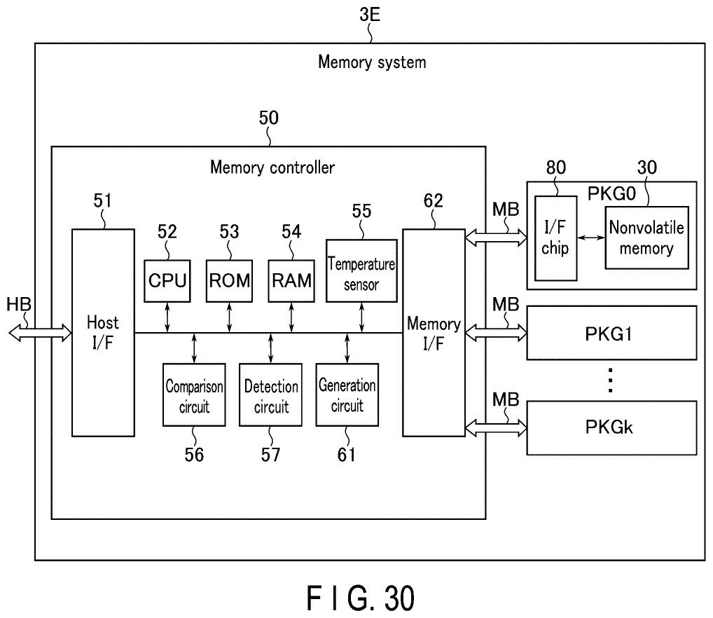

A configuration of the memory system 3E will be described with reference to FIG. 30. FIG. 30 is a block diagram showing an example of a configuration of a memory system 3E. As shown in FIG. 30, the memory system 3E includes a plurality of packages PKG0 to PKGk (where k is an integer equal to or greater than 1). Hereinafter, in a case where packages PKG0 to PKGk are not distinguished from each other, they will be simply referred to as a “package PKG”. The package PKG includes the nonvolatile memory 30 and an interface (I/F) chip 80.

A configuration of the nonvolatile memory 30 is similar to that shown in FIG. 3 described in the first embodiment.

The interface chip 80 is a device configured to manage communications between the memory controller 50 and the nonvolatile memory 30. The interface chip 80 is coupled to the nonvolatile memory 30 via a bus. The interface chip 80 is coupled to the memory controller 50 via the memory bus MB.

The memory controller 50 is, for example, an SSD controller. A configuration of the memory controllers 50 is similar to that of FIG. 3 described in the first embodiment. The memory controller 50 controls the nonvolatile memory 30 in each package PKG via the memory bus MB based on a request signal received from the host 2 or a voluntary processing request.

Meanwhile, the comparison circuit 56, the detection circuit 57, and the generation circuit 61 may be mounted on the interface chip 80, not the memory controller 50.

### 3.2 Structure of Memory System

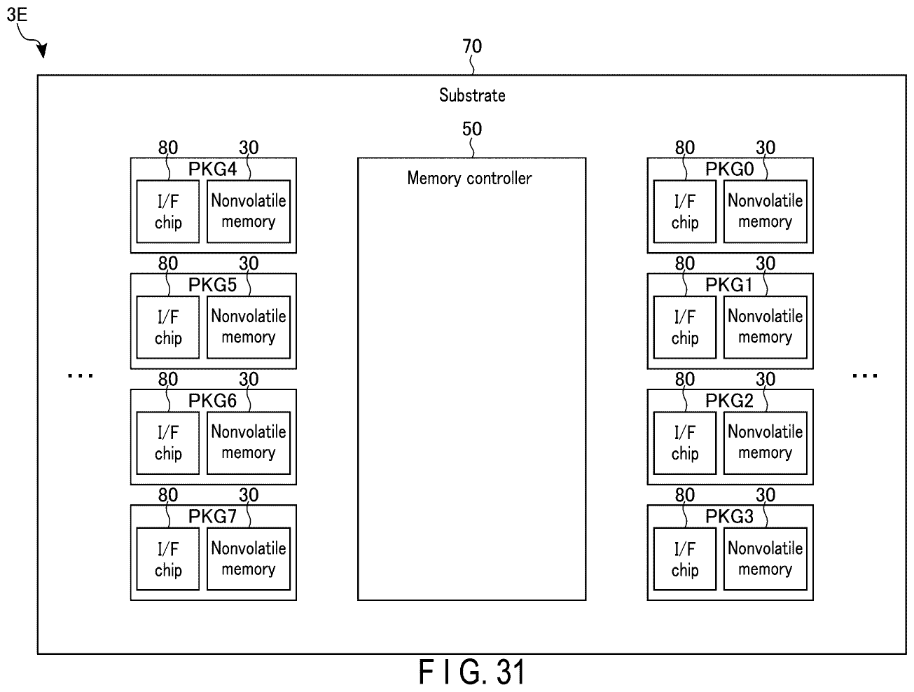

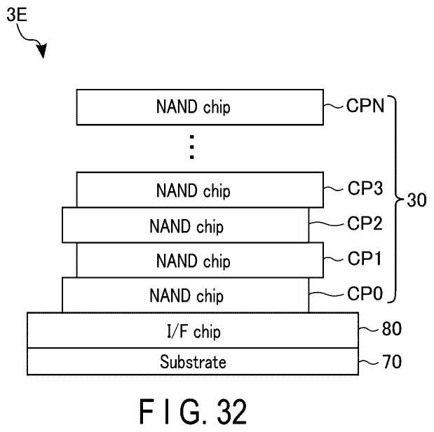

A structure of the memory system 3E will be described with reference to FIG. 31 and FIG. 32. FIG. 31 is a planar view showing an example of the structure of the memory system 3E. FIG. 32 is a cross-sectional view showing an example of a structure of each package PKG in the memory system 3E. FIG. 31 and FIG. 32 omit illustration of the memory bus MB and a bus coupling the interface chip 80 and the nonvolatile memory 30.

As shown in FIG. 31, the plurality of packages PKG and the memory controller 50 are provided on the substrate 70. A plurality of packages PKG including the packages PKG0 to PKG3 are provided on the right side of the memory controller 50. The packages PKG0 to PKG3 are spaced apart from each other in the vertical direction. A plurality of packages PKG including the packages PKG4 to PKG7 are provided on the left side of the memory controller 50. The packages PKG4 to PKG7 are spaced apart from each other in the vertical direction.

As shown in FIG. 32, the interface chip 80 is provided on the substrate 70. On the interface chip 80, (N+1) NAND chips CP are stacked in the order of the NAND chips CP0, CP1, CP2, CP3, . . . , CPN from the side close to the substrate 70.

In the memory system 3E that has the structure as described above, a respective one NAND chip CP is in contact with one or two other NAND chips in the nonvolatile memory 30. Therefore, in the nonvolatile memory 30, a value of the temperature sensor data Temp of the temperature sensor 35 is approximately equal between the NAND chips CP. Furthermore, a physical distance between the packages PKG0 to PKG3 is relatively short. Similarly, a physical distance between the packages PKG4 to PKG7 is relatively short. Therefore, a value of the temperature sensor data Temp of the temperature sensor 35 of each NAND chip CP in the nonvolatile memory 30 is most likely to be approximately equal between the packages PKG0 to PKG3, too. The temperature sensor data Temp of the temperature sensor 35 of each NAND chip CP in the nonvolatile memory 30 is most likely to be approximately equal between the packages PKG4 to PKG7, too.

On the other hand, a physical distance between a set of the packages PKG0 to PKG3 (hereinafter referred to as a “first package set”) and a set of the packages PKG4 to PKG7 (hereinafter referred to as a “second package set”) is relatively long. Therefore, a value of the temperature sensor data Temp of the temperature sensor 35 of each NAND chip CP in the nonvolatile memory 30 is most likely to be relatively greatly different between the first package set and the second package set.

### 3.3 Operation

A defective temperature sensor detection operation of the information processing system 1E will be described. A flowchart showing an example of the defective temperature sensor detection operation in the information processing system 1E is similar to that shown in FIG. 11 described in the first embodiment.

As described above, in the nonvolatile memory 30, the temperature sensor data Temp of the temperature sensor 35 is approximately equal between the NAND chips CP. Therefore, in the present embodiment, the memory controller 50 executes the defective temperature sensor detection operation on the nonvolatile memory 30 for each package PKG, as in the first embodiment.

### 3.4 Advantageous Effect of Third Embodiment

The third embodiment produces the advantageous effects similar to those of the first embodiment.

Furthermore, in the memory system 3E according to the present embodiment, the memory controller 50 executes the defective temperature sensor detection operation on the nonvolatile memory 30 for each package PKG, as in the first embodiment. The memory controller 50 does not execute the defective temperature sensor detection operation between one package PKG and the other packages PKG. Thus, according to the present embodiment, the defective temperature sensor detection operation can be performed more effectively.

Meanwhile, as described above, a value of the temperature sensor data Temp of the temperature sensor 35 of each NAND chip CP in the nonvolatile memory 30 is most likely to be approximately equal between the packages PKG0 to PKG3 and between the packages PKG4 to PKG7. Thus, between the packages PKG0 to PKG3, the defective temperature sensor detection operation may be performed using three corresponding NAND chips CP. For example, the defective temperature sensor detection operation may be performed using the temperature sensor data Temp of the corresponding NAND chip CP of the package PKG0, the temperature sensor data Temp of the corresponding NAND chip CP of the package PKG1, and the temperature sensor data Temp of the corresponding NAND chip CP of the package PKG2. Meanwhile, corresponding NAND chips CP are, for example, those assigned the same reference symbol (number). The defective temperature sensor detection operation may be performed in a similar manner between the packages PKG4 to PKG7.

The first modification, the second modification, and the third modification of the first embodiment are applicable to the third embodiment.

### 4. Fourth Embodiment

A configuration of the information processing system 1F according to a fourth embodiment will be described. The information processing system 1F according to the fourth embodiment is different from that of the first embodiment in terms of the configurations of a temperature sensor 35F and a sequencer 40F of the NAND chip CP. Hereinafter, the following description will in principle concentrate on the features different from the first embodiment.

### 4.1 Configuration of NAND Chip

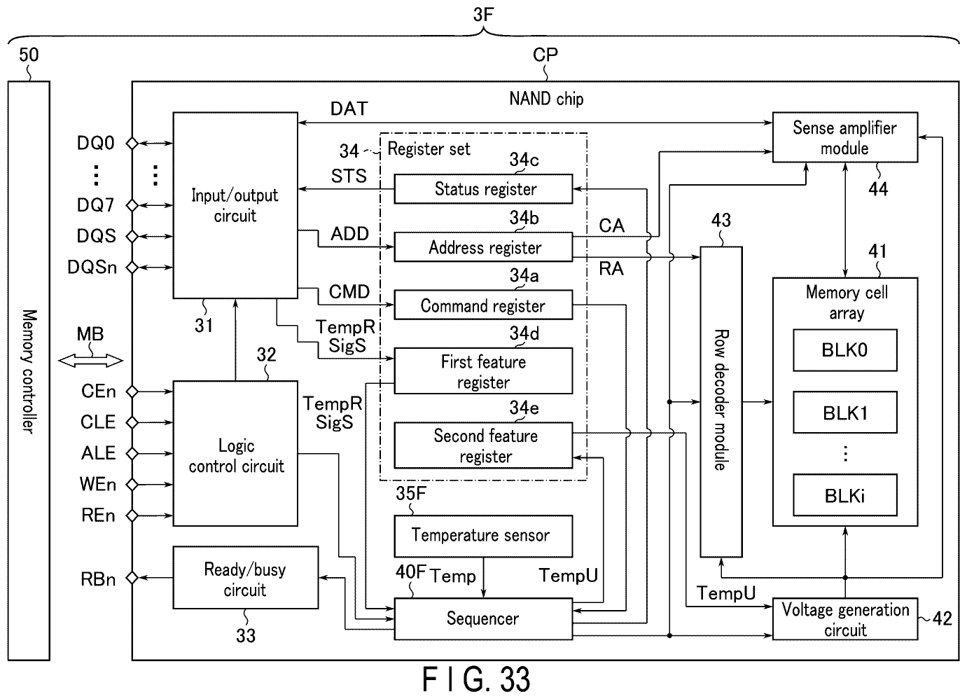

A configuration of the NAND chip CP will be described with reference to FIG. 33. FIG. 33 is a block diagram showing an example of a configuration of the NAND chip CP. FIG. 33 shows a configuration of one of the NAND chips CP included in the nonvolatile memory 30. The other NAND chips CP included in the nonvolatile memory 30 have similar configurations to the configuration shown in FIG. 33. FIG. 33 shows the memory controller 50, too.

As shown in FIG. 33, the temperature sensor 35F measures a temperature of the NAND chip CP. The temperature sensor 35F is a temperature measurement circuit that is prepared by applying, for example, a band gap reference circuit, etc., and is mounted inside the semiconductor device 30. Other examples of the temperature sensor 35F include a thermocouple. For example, the temperature sensor 35F measures a temperature of the memory cell array 41 inside the NAND chip CP. The temperature sensor 35F transmits a measured temperature as the temperature sensor data Temp to the sequencer 40F. The temperature sensor 35F may not directly measure a temperature of the memory cell array 41. For example, the temperature sensor 35F may measure a temperature of, for example, a portion other than the memory cell array 41 inside the NAND chip CP. The temperature sensor 35F will be described later in detail.

The sequencer 40F controls the overall operation of the NAND chip CP as in the first embodiment. For example, the sequencer 40F controls the ready/busy circuit 33, the voltage generation circuit 42, the row decoder module 43, and the sense amplifier module 44 based on the command CMD stored in the command register 34a. For example, the sequencer 40F executes the read operation, the write operation, and the erase operation. Furthermore, the sequencer 40F stores the temperature sensor data Temp acquired from the temperature sensor 35F as the status information STS in the status register 34c, and outputs the stored data to the memory controller 50 via the input/output circuit 31. The temperature sensor data Temp may be output to the memory controller 50 not as the status information STS but as information other than the status information STS. Furthermore, the sequencer 40F stores the replacement temperature data TempR and the signal SigS received from the memory controller 50 in the first feature register 34d.

The sequencer 40F acquires the replacement temperature data TempR and the switch signal SigS from the first feature register 34d. The sequencer 40F selects either the temperature sensor data Temp acquired from the temperature sensor 35F or the replacement temperature data TempR based on the switch signal SigS, and transmits the selected temperature data as the use temperature data TempU to the second feature register 34e. That is, the NAND chip CP (sequencer 40F) switches the use temperature data TempU based on the switch signal SigS. As described above, the sequencer 40F can switch a temperature measured by the temperature sensor 35F and a temperature input from an outside and output the switched temperature as the use temperature data TempU.

### 4.2 Configuration of Temperature Sensor

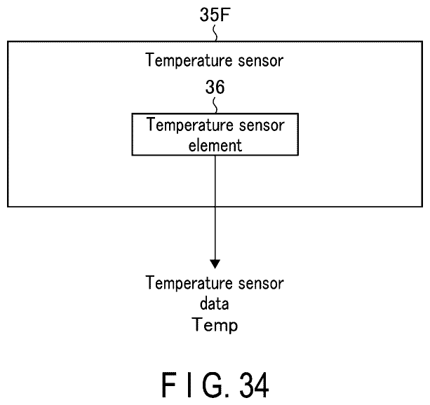

A configuration of the temperature sensor 35F of the NAND chip CP will be described with reference to FIG. 34. FIG. 34 is a circuit diagram showing an example of the configuration of the temperature sensor 35F. As shown in FIG. 34, the temperature sensor 35F includes a temperature sensor element 36.

The temperature sensor element 36 measures a temperature. The temperature sensor element 36 transmits the measured temperature sensor data Temp to an outside of the temperature sensor 35F. The temperature sensor data Temp output to the outside of the temperature sensor 35F is transmitted to the sequencer 40F.

### 4.3 Operation

A defective temperature sensor detection operation of the information processing system 1F will be described. A flowchart showing an example of the defective temperature sensor detection operation in the information processing system 1F is similar to that shown in FIG. 11 described in the first embodiment.

In the present embodiment, the memory controller 50 executes the defective temperature sensor detection operation on the nonvolatile memory 30 as in the first embodiment.

### 4.4 Advantageous Effect of Fourth Embodiment

In the memory system 3F according to the present embodiment, the temperature sensor 35F measures a temperature and transmits the measured temperature sensor data Temp to the sequencer 40F. The sequencer 40F switches, based on the switch signal SigS, the temperature sensor data Temp acquired from the temperature sensor 35F and the replacement temperature data TempR input from the outside, and outputs the switched data as the use temperature data TempU. The use temperature data TempU output from the sequencer 40F is stored in the second feature register 34e. As described above, in each of the NAND chips CP, the use temperature data TempU can be rewritten. In this manner, the present embodiment produces advantageous effects similar to those of the first embodiment.

The first modification, the second modification, and the third modification of the first embodiment are applicable to the fourth embodiment. The nonvolatile memory 30 according to the fourth embodiment is applicable to the third embodiment.

### 5. Others

As described above, a memory system (3) according to an embodiment includes a first semiconductor device (30) and a controller (50). The first semiconductor device (30) includes a first chip (CP0). The first chip (CP0) includes a first temperature sensor (35). The controller (50) includes a comparison circuit (56) and a detection circuit (57). The comparison circuit (56) makes a comparison between a first measurement temperature (Temp0) measured by the first temperature sensor (35) and first temperature data (Temp1) and outputs a result of the comparison as a first comparison result (ResA0), and makes a comparison between the first measurement temperature (Temp0) and second temperature data (Temp2) and outputs a result of the comparison as a second comparison result (ResA2). The detection circuit (57) performs detection of a defect in the first temperature sensor (35) based on the first comparison result (ResA0) and the second comparison result (ResA2), and outputs a result of the detection as a first detection result (ResD0=SigS0). The first chip (CP0) switches a first use temperature (TempU0) based on the first detection result (ResD0=SigS0).

The embodiments are not limited to those described in the above, and various modifications can be made.

Furthermore, the order of the steps in the flowchart described in the above embodiments may be altered to the extent possible.

The above embodiments described the exemplary case in which the semiconductor device 30 is a nonvolatile memory; however, the semiconductor device 30 is not limited to such a nonvolatile memory. That is, the chip CP included in the semiconductor device 30 is not limited to a NAND flash memory and may be a DRAM or an SRAM. The chip CP included in the semiconductor device 30 may be another memory or another device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a first semiconductor device including a first chip having a first temperature sensor; and
a controller including:
a comparison circuit configured to make a comparison between a first measurement temperature measured by the first temperature sensor and first temperature data and output a result of the comparison as a first comparison result, and make a comparison between the first measurement temperature and second temperature data and output a result of the comparison as a second comparison result; and
a detection circuit configured to perform detection of a defect in the first temperature sensor based on the first comparison result and the second comparison result, and output a result of the detection as a first detection result,
wherein the first chip switches a first use temperature based on the first detection result.

2. The memory system according to claim 1, wherein the controller further includes a generation circuit configured to generate a first input temperature corresponding to the first temperature sensor based on the first temperature data and the second temperature data,
in a case of the first detection result showing that the first temperature sensor is in a first state, the first chip uses the first measurement temperature as the first use temperature, and
in a case of the first detection result showing that the first temperature sensor is in a second state different from the first state, the first chip uses the first input temperature as the first use temperature.

3. The memory system according to claim 1, wherein the first semiconductor device further includes:
a second chip having a second temperature sensor; and
a third chip having a third temperature sensor,
the first temperature data is a temperature measured by the second temperature sensor, and
the second temperature data is a temperature measured by the third temperature sensor.

4. The memory system according to claim 1, wherein the comparison circuit is configured to:
output, as the first comparison result, an absolute value of a difference between the first measurement temperature and the first temperature data; and
output, as the second comparison result, an absolute value of a difference between the first measurement temperature and the second temperature data.

5. The memory system according to claim 4, wherein the first semiconductor device further includes:
a second chip having a second temperature sensor; and
a third chip having a third temperature sensor,
the first temperature data is a temperature measured by the second temperature sensor,
the second temperature data is a temperature measured by the third temperature sensor, and
the first chip is arranged so that the first chip is physically adjacent to the second chip and the third chip.

6. The memory system according to claim 4, wherein the detection circuit includes:
a determination circuit configured to make a determination as to whether the first comparison result is smaller than a first threshold and output a result of the determination as a first determination result, and make a determination as to whether the second comparison result is smaller than the first threshold and output a result of the determination as a second determination result; and
an AND circuit configured to perform an AND operation of the first determination result and the second determination result, and transmit a result of the AND operation as the first detection result to the first chip.

7. The memory system according to claim 6, wherein in a case where the first comparison result is smaller than the first threshold, the determination circuit outputs a first value as the first determination result,
in a case where the first comparison result is equal to or greater than the first threshold, the determination circuit outputs a second value as the first determination result,
in a case where the second comparison result is smaller than the first threshold, the determination circuit outputs a third value as the second determination result,
in a case where the second comparison result is equal to or greater than the first threshold, the determination circuit outputs a fourth value as the second determination result,
in a case where the first determination result is the first value and the second determination result is the third value, the AND circuit outputs, as the first detection result, a fifth value indicating that the first temperature sensor is in a first state, and
in a case where the first determination result is the first value and the second determination result is the fourth value, a case where the first determination result is the second value and the second determination result is the third value, or a case where the first determination result is the second value and the second determination result is the fourth value, the AND circuit outputs, as the first detection result, a sixth value indicating that the first temperature sensor is in a second state different from the first state.

8. The memory system according to claim 6, wherein the detection circuit further includes an OR circuit configured to perform an OR operation of the first determination result and the second determination result, and output a result of the OR operation as a second detection result.

9. The memory system according to claim 2, wherein the generation circuit is configured to output, as the first input temperature, an average value of the first temperature data and the second temperature data.

10. The memory system according to claim 9, wherein
the first semiconductor device further includes:
a second chip having a second temperature sensor; and
a third chip having a third temperature sensor,
the first temperature data is a temperature measured by the second temperature sensor,
the second temperature data is a temperature measured by the third temperature sensor, and
the first chip is arranged so that the first chip is physically adjacent to the second chip and the third chip.

11. The memory system according to claim 1, wherein the controller further includes:
a second temperature sensor; and
a generation circuit configured to generate a second measurement temperature measured by the second temperature sensor, as a first input temperature corresponding to the first temperature sensor,
in a case of the first detection result showing that the first temperature sensor is in a first state, the first chip uses the first measurement temperature as the first use temperature, and
in a case of the first detection result showing that the first temperature sensor is in a second state different from the first state, the first chip uses the first input temperature as the first use temperature.

12. The memory system according to claim 1, wherein the semiconductor device further includes a second chip having a second temperature sensor,
the controller further includes a third temperature sensor,
the first temperature data is a temperature measured by the second temperature sensor, and
the second temperature data is a temperature measured by the third temperature sensor.

13. The memory system according to claim 1, further comprising a second semiconductor device including a second chip having a second temperature sensor,
wherein the comparison circuit is configured to make a comparison between a second measurement temperature measured by the second temperature sensor and third temperature data, output a result of the comparison as a third comparison result, make a comparison between the second measurement temperature and fourth temperature data, and output a result of the comparison as a fourth comparison result,
the detection circuit is configured to perform detection of a defect in the second temperature sensor based on the third comparison result and the fourth comparison result, and output a result of the detection as a second detection result, and
the second chip switches a second use temperature based on the second detection result.

14. The memory system according to claim 13, wherein the controller further includes a generation circuit configured to generate a second input temperature corresponding to the second temperature sensor based on the third temperature data and the fourth temperature data,
in a case of the second detection result showing that the second temperature sensor is in a first state, the second chip uses the second measurement temperature as the second use temperature, and
in a case of the second detection result showing that the second temperature sensor is in a second state different from the first state, the second chip uses the second input temperature as the second use temperature.

15. An information processing system comprising:
the memory system according to claim 1; and
a host,
wherein the controller further includes a second temperature sensor,
the host includes a third temperature sensor,
the first temperature data is a temperature measured by the second temperature sensor, and
the second temperature data is a temperature measured by the third temperature sensor.

16. An information processing system comprising:
a memory system including:
a first semiconductor device including a first chip having a first temperature sensor; and
a controller configured to control the first semiconductor device; and
a host including:
a comparison unit configured to make a comparison between a first measurement temperature measured by the first temperature sensor and first temperature data and output a result of the comparison as a first comparison result, and make a comparison between the first measurement temperature and second temperature data, and output a result of the comparison as a second comparison result; and
a detection unit configured to perform detection of a defect in the first temperature sensor based on the first comparison result and the second comparison result, and output a result of the detection as a first detection result,
wherein the first chip switches a first use temperature based on the first detection result.

17. The information processing system according to claim 16, wherein the host further includes a generation unit configured to generate a first input temperature corresponding to the first temperature sensor based on the first temperature data and the second temperature data,
in a case of the first detection result showing that the first temperature sensor is in a first state, the first chip uses the first measurement temperature as the first use temperature, and
in a case of the first detection result showing that the first temperature sensor is in a second state different from the first state, the first chip uses the first input temperature as the first use temperature.

18. A semiconductor device comprising:
a first chip having a first temperature sensor, wherein the first chip switches a first use temperature based on a first signal input from an outside.

19. The device according to claim 18, wherein the first temperature sensor includes:
a first register configured to store a measured temperature;
a second register configured to store a temperature input from an outside; and
a multiplexer into which a first measurement temperature stored in the first register and a first input temperature stored in the second register are input, and which is configured to switch between the first measurement temperature and the first input temperature and output the switched first measurement temperature or first input temperature as the first use temperature based on the first signal.

20. The device according to claim 19, wherein the first chip further includes:
a third register configured to store the first signal and the first input temperature; and
a fourth register configured to store the first use temperature.
